(19) United States
(12) Patent Application Publication
(10) Pub. No.: US 2004/0196719 A1
(43) Pub. Date: Oct. 7, 2004

(54) Semiconductor memory device having reduced current dissipation in data holding mode

(75) Inventors: Kengo Aritomi, Hyogo (JP); Yoshinori Inoue, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/673,139

(22) Filed: Sep. 30, 2003

(30) Foreign Application Priority Data
Apr. 4, 2003 (JP) 2003-101641(P)

(51) Int. Cl. G11C 7/00

(52) U.S. Cl. 365/222

(57) ABSTRACT

In a semiconductor memory device, there are provided refresh timers issuing refresh requests at different periods, and refresh address generation circuits generating refresh addresses in accordance with the respective refresh requests. In a row select circuit, it is set for each row according to which, of the refresh addresses different from each other in issuance period, a corresponding word line is to be selected. Each word line can be refreshed in a different refresh cycle, and only a word line of pause refresh failure is refreshed in a shorter cycle while the other word lines are refreshed in a longer cycle. Current dissipation can be reduced in a self-refresh mode.

### BACKGROUND OF THE INVENTION

1. Field of the Invention

The present invention relates to a semiconductor memory device and, particularly, to a dynamic semiconductor memory device requiring for regular refresh of stored data. More particularly, the present invention relates to a configuration for reducing current dissipation in a data holding mode.

2. Description of the Background Art

In a dynamic type semiconductor memory device such as a DRAM (Dynamic Random Access Memory), a capacitor is provided in a memory cell storing data. The capacitor stores data in an electric charge form, and one memory cell is usually formed of one transistor and one capacitor. Therefore, a DRAM cell occupies a smaller area as compared with a SRAM cell requiring four transistors and two load elements. Hence, since a large storage capacity memory can be implemented in a reduced area, DRAM is widely employed as a large storage capacity memory.

In DRAM, however, since data is stored in a capacitor in an electric charge form, storage data disappears if accumulated electric charges flows out by leakage of the charges into a substrate region or an interlayer insulating film. For this reason, in DRAM, refresh of rewriting a stored data is performed regularly. There are two operating modes to perform refresh: an auto-refresh mode in which refresh is executed in accordance with an externally supplied refresh command between data accesses; and a self-refresh mode in which a refresh timing and a refresh address are generated within the memory and refresh is executed during a data holding mode in which no data access is made over a long period of time.

In the self-refresh mode, an internally provided refresh timer performs a time measuring operation to issue refresh requests at prescribed time intervals. A refresh row designated by a refresh address from a refresh address counter is selected in accordance with a refresh request, for performing data rewriting (restoring). A count of the refresh address counter is updated when a refresh is executed.

In the self-refresh mode, only data holding is performed. Accordingly, in the data holding mode, it is desirable to reduce power consumption to a level as lowest as possible. Especially, in a portable equipment application, a battery is employed as a power supply, and therefore, power consumption is desired to reduce from the viewpoint of a lifetime of a battery as well.

A current consumption in a data holding mode occurs by a refresh operation. Therefore, with reduced number of times of refresh, a current consumption can be decreased. A time interval between refreshes executed on a common memory cell is called a refresh cycle, which is set at 64 msec (milliseconds), for example. There is a case where charge holding characteristics of memory cell capacitors are different from each other over a common chip because of fluctuation in process parameter during fabrication, a pattern deviation, particles such etching residue and others.

A refresh cycle is set in consideration of a charge holding characteristic of the worst case. Therefore, a memory cell having a capacitor of excellent charge holding characteristic is subjected to refresh under a state where a sufficient amount of electric charges are accumulated. Generally, memory cells inferior in charge holding characteristic are much fewer than memory cells excellent in charge holding characteristic. Accordingly, if refresh can be executed in a refresh cycle depending on a charge holding characteristic (a pause refresh characteristic) of each memory cell, by refreshing a memory cell excellent in charge holding characteristic in a longer refresh cycle, the number of times of refresh per unit time can be reduced. Here, a pause refresh characteristic means a charge holding characteristic in a standby state.

Following prior art documents 1 to 10 disclose the configuration, in which a refresh cycle for a memory cell inferior in charge holding characteristic is made shorter than that for a memory cell excellent in charge holding characteristic.

In Japanese Patent Laying-Open No. 2002-133862, a memory array is divided into a plurality of cell arrays and, in a self-refresh mode, only a cell array excellent in data holding characteristic is utilized as a data holding region. In this case, the correspondence relation between an address of a cell array and a refresh address is changed. According to a configuration of this prior art reference, since no refresh is performed on a memory cell inferior in data holding characteristic, a refresh cycle can be made longer. However, in a case where a great amount of data, such as image data for example, is utilized, all of the cell arrays have to be utilized. In this case, a refresh cycle is set considering the worst case, and therefore, refresh characteristic can not be set depending on data holding characteristic of each memory cell.

In Japanese Patent Laying-Open No. 2001-250378, a defect address is programmed in a cache and in a data holding mode, data in a defect address region of the DRAM is transferred to an SRAM cache, and in a normal operating mode, the data is transferred to the DRAM array from the SRAM cache. Refresh in a DRAM is executed in a refresh cycle of a memory cell excellent in data holding characteristic to thereby reduce the number of times of refresh. However, data in a defect address region inferior in data holding characteristic are saved in a cache region and upon transition to the normal operating mode, the data saved in the SRAM cache is loaded to a corresponding region of the DRAM, which makes the control thereon complicated. Especially, data in the defect address region is transferred to the SRAM cache and rewritings of cache data are required upon both entry into and exit from the data holding mode, resulting in a problem that transition to a normal data access mode cannot be performed at a high speed upon completion of data holding mode.

In Japanese Patent Laying-Open No. 11-39861, comparison is made between a defect address designating a defective row inferior in data holding characteristic and a refresh address, and when coincidence is detected in address bits except a predetermined number of upper bits, the defective row and normal row are refreshed together. In the case of a construction of this prior art, refreshes on defect rows inferior in refresh characteristic is increased in number of times than normal rows, and a refresh cycle can be made effectively longer. In the case of a configuration of this prior art, however, it is required to simultaneously select a defect, row and a normal row in different memory blocks from each other, and a defective row and a normal row in a common memory block can not be refreshed simultaneously, which imposes restriction on a relation between a defective row and a normal row to be simultaneously selected. Furthermore, in the case where a normal row and a defect row are both refreshed when the defect row is refreshed, the number of refresh rows increases as compared to the normal data read mode of operation, which in turn increases a refresh current (average current).

In Japanese Patent Laying-Open No. 8-45271, when an address of a defective row inferior in data holding characteristic coincides in prescribed bits with a refresh address, refresh on the defective row is performed while interrupting refresh on a normal row. While all the memory cells are refreshed, a defective row is refreshed a plurality of times, and therefore, a refresh cycle is shortened as a whole. In a case where there exist a plurality of defective rows inferior in data holding characteristic, a refresh cycle for a normal row is increased accordingly, leading to a possibility that a data holding characteristic of normal rows cannot be ensured.

In Japanese Patent Laying-Open No. 6-44773, similarly to Japanese Patent Laying-Open No. 8-45271, an address of a defective row inferior in data holding characteristic is stored and in a refresh operation, refresh on the defective row is inserted during a refresh operation. Therefore, a refresh cycle for a normal row is made longer. In this case as well, when only one defective row is present, an effective increase in refresh cycle does not occur, and correct refresh of stored data in normal rows can be implemented. If a plurality of defective rows are present, a refresh cycle for a normal row is made longer accordingly, leading to possibility of not ensuring data holding of normal rows.

In Japanese Patent Laying-Open No. 5-101651, when a refresh of a defective row is reached, refresh of a normal row is interrupted to perform a refresh operation the defective row. Accordingly, in a case where a refresh cycle is altered on a memory block unit, interruption of refresh on a memory block of defective data holding characteristic is inserted to increase a refresh cycle for a normal memory block, leading to a problem of not guaranteeing data holding characteristic of a normal memory block.

In Japanese Patent Laying-Open No. 3-283180, a defective row is refreshed after refresh on normal row in each refresh operation period. Therefore, a period when refresh is executed is extended, transition from a self-refresh mode to a normal operating mode requires an increased time, resulting in a problem that a data holding mode cannot be released at high speed.

In Japanese Patent Laying-Open No. 62-223893, refresh operation is configured to be simultaneously executed on a normal row and a defective row in memory blocks different from each other, when addressing a defective row inferior in data holding characteristic for refreshing. Therefore, a refresh cycle for a defective row is shorter than that for a normal row equivalently. In this case as well, however, while refresh is executed on a defective row, an average current consumption increases since the number of word lines driven to a selected state simultaneously in refreshing a defective row is different from that in refresh on a normal row.

In Japanese Patent Laying-Open No. 2001-184860, there is shown a configuration in which an oscillating cycle of an oscillation circuit determining a refresh cycle in self-refresh is made programmable. This prior art aims to suppress a fluctuation in refresh cycle caused by a variation in oscillating cycle of the oscillation circuit derived from fluctuations in process parameters or the like, to optimize a refresh cycle. In this prior art, however, a common refresh cycle is set to all the memory cells and no consideration is given to the change in refresh cycles between a memory cell excellent in data holding characteristic and a memory cell inferior in data holding characteristic.

In WO 96-28825, a refresh cycle is set for each memory block. In this prior art, a refresh clock generation circuit issuing refresh requests is provided for each memory block and a block address generation circuit generates a block address designating a corresponding memory block and a in-block address by driving an oscillator. Therefore, when refresh is executed in one block, no refresh can be executed in another block. This prior art does not consider a conflict in issuance of refresh request between memory blocks, and does not provide description of how to treat the conflict.

### SUMMARY OF THE INVENTION

It is an object of the present invention to provide a semiconductor memory device capable of correctly performing refresh in a fresh cycle depending on a data holding characteristic of a memory cell.

It is another object of the present invention to provide a semiconductor memory device capable of correctly performing refresh according to a data holding characteristic even in a memory block unit.

A semiconductor memory device according to the present invention includes: a plurality of memory cells, arranged in rows and columns, each storing information; a first refresh timer for issuing, when made active, a first refresh request in a first cycle; a first refresh address generation circuit for generating and outputting a first refresh address in accordance with the first refresh request; a second refresh timer for issuing, when made active, a second refresh request in a cycle shorter than the first cycle; a second refresh address generation circuit for generating a second refresh address independently of the first refresh address; and a plurality of row select circuits, provided corresponding to respective memory cell rows, each driving, when made active, a corresponding row to a selected state in accordance with an applied address signal.

Each row select circuit drives an addressed row to a selected state in accordance with one of the first refresh address and the second refresh address. Each row select circuit is alternatively determined as to which of the first and second refresh addresses to respond to.

With the first and second refresh address generation circuits employed, a refresh address can be selectively generated depending on a data holding characteristic. Further, in the row select circuit, a corresponding refresh address is selected in accordance with a refresh request, and refresh can be performed in accordance with a refresh address generated according to an individual refresh cycle without interrupting a refresh. Especially, a refresh address to which a row select circuit responds is alternatively set to one of the first and second refresh addresses, and the correct refresh on a memory cell row can be implemented in a refresh cycle according to the data holding characteristic.

A refresh arbitration circuit is preferably employed to enable correct refresh in an optimal refresh cycle while preventing a conflict between refreshes even if a refresh cycle is set in a block by block basis.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram schematically showing an overall configuration of a semiconductor memory device according to the present invention;

FIG. 2 is a diagram schematically showing a configuration of a refresh control circuit shown in FIG. 1;

FIG. 3 is a signal waveform diagram representing an operation of a refresh circuit shown in FIG. 2;

FIG. 4 is a diagram showing a configuration example of a clock generation circuit shown in FIG. 2;

FIG. 5 is a timing chart representing an operation of the clock generation circuit shown in FIG. 2;

FIG. 6 is a diagram schematically showing a configuration of a programmable refresh timer shown in FIG. 2;

FIG. 7 is a diagram showing a configuration example of a count control circuit shown in FIG. 6;

FIG. 8 is a timing chart representing an operation of the count control circuit shown in FIG. 7;

FIG. 9 is a diagram showing a configuration of a refresh program circuit shown in FIG. 6;

FIG. 10 is a diagram showing a configuration of the refresh program circuit shown in FIG. 6;

FIG. 11 is a table showing, in a list, program states of the refresh program circuits shown in FIGS. 9 and 10;

FIG. 12 is a diagram schematically showing a configuration of a count circuit shown in FIG. 6;

FIG. 13 is a diagram showing a configuration example of a one-bit counter shown in FIG. 12;

FIG. 14 is a timing chart representing an operation in the one-bit counter shown in FIG. 13;

FIG. 15 is a diagram showing a configuration of an upper one-bit counter shown in FIG. 12;

FIG. 16 is a timing chart representing an operation in the one-bit counter shown in FIG. 15;

FIG. 17 is a timing chart representing an operation of the one-bit counter showing in FIG. 15;

FIG. 18 is a timing chart representing an operation of count circuit of the one-bit counters shown in FIGS. 13 and 15;

FIG. 19 is a timing chart showing operations in the count circuits of the one-bit counters shown in FIGS. 13 and 15;

FIG. 20 is a diagram showing a configuration example of a refresh activation circuit shown in FIG. 2;

FIG. 21 is a signal waveform diagram representing an operation of the refresh activation circuit shown in FIG. 20;

FIG. 22 is a diagram schematically showing a configuration of a section of a row-related control circuit shown in FIG. 1;

FIG. 23 is a diagram schematically showing a configuration of a refresh address generation circuit shown in FIG. 2;

FIG. 24 is a diagram showing a configuration example of an address update control circuit shown in FIG. 23;

FIG. 25 is a signal waveform diagram representing an operation of the address update control circuit shown in FIG. 24;

FIG. 26 is a diagram schematically showing a configuration of an address counter shown in FIG. 23;

FIG. 27 is a diagram showing a configuration example of a one-bit counter shown in FIG. 26;

FIG. 28 is a signal waveform diagram representing an operation of the one-bit counter shown in FIG. 27;

FIG. 29 is a signal waveform diagram representing an operation of an address counter shown in FIG. 26;

FIG. 30 is a diagram showing a configuration example of an address select circuit shown in FIG. 1;

FIG. 31 is a signal waveform diagram representing an operation of the address select circuit shown in FIG. 30;

FIG. 32 is a diagram schematically showing a configuration of a first row select circuit shown in FIG. 1;

FIG. 33 is a diagram showing a configuration example of a fuse program circuit shown in FIG. 32;

FIG. 34 is a diagram schematically showing a configuration of a second row select circuit shown in FIG. 1;

FIG. 35 is a diagram showing a configuration example of a fuse program circuit shown in FIG. 34;

FIG. 36 is a diagram schematically showing a configuration of a row drive circuit shown in FIG. 1;

FIG. 37 is a diagram schematically showing a configuration of a memory cell array shown in FIG. 1;

FIG. 38 is a diagram schematically showing a configuration of a sub-word driver band shown in FIG. 37;

FIG. 39 is a diagram showing a configuration example of a sub-decoder shown in FIG. 37;

FIG. 40 is a diagram schematically showing a configuration of the row-related control circuit shown in FIG. 1;

FIG. 41 is a signal waveform diagram representing an operation of the row-related control circuit shown in FIG. 40;

FIG. 42 is a diagram showing a modification of a refresh timer shown in FIG. 2;

FIG. 43 is a signal waveform diagram showing operations in the refresh timer shown in FIG. 42;

FIG. 44 is a signal waveform diagram representing a refresh operation when the refresh timer shown in FIG. 42 is employed;

FIG. 45 is a diagram schematically showing a configuration of a sense amplifier control section of the row-related circuit shown in FIG. 1; and

FIG. 46 is a signal waveform diagram representing an operation of the sense amplifier control section shown in FIG. 45.

### DESCRIPTION OF THE PREFERRED EMBODIMENTS

First Embodiment

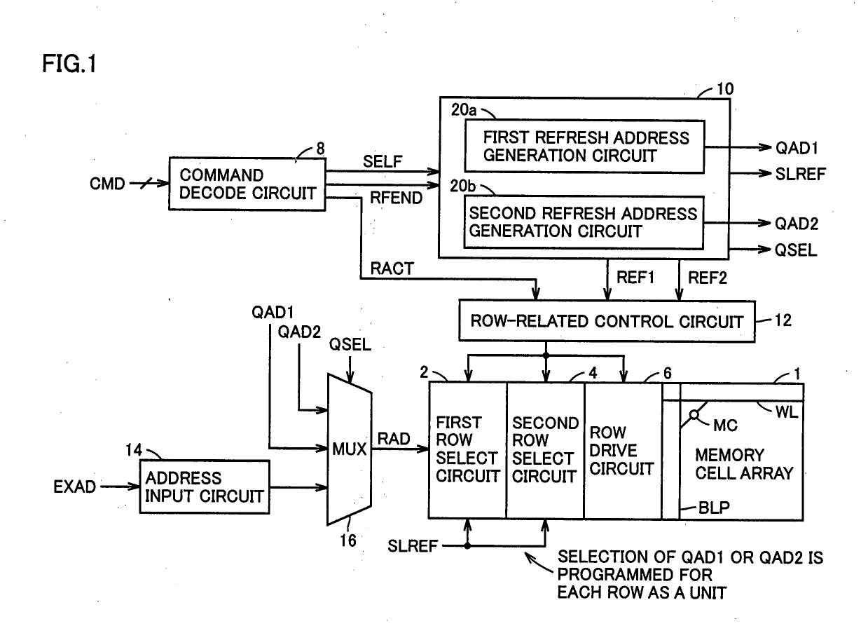

FIG. 1 is a diagram showing an overall configuration of a semiconductor memory device according to the present invention. In FIG. 1, the semiconductor memory device includes: a memory cell array 1 having a plurality of memory cells MC arranged in rows and columns; a first row select circuit 2 for generating a row select signal selecting a memory cell row in memory cell array 1; a second row select circuit 4, provided in parallel to the first row select circuit 2, driving an addressed row in memory cell array 1 to a selected state in accordance with a given address signal; and a row drive circuit 6 for driving selected rows in memory cell array 1 to a selected state in accordance with row select signals outputted from first and second row select circuit 2 and 4.

In memory cell 1, a word line WL is provided corresponding to each memory cell row and a pair of bit lines BLP is provided corresponding to each column of memory cells MC.

First and second row select circuits 2 and 4 have, their respective row address signals to respond to, programmed. By arranging the first and second row select circuits in parallel to each other, refresh on a word line is performed at an optimal cycle according to a pause refresh characteristic (data holding characteristic). Specifically, in a self-refresh mode, refresh addresses QAD1 and QAD2 are generated at different periods and first and second row select circuits 2 and 4 have the corresponding refresh addresses fixedly set, and thus, refresh operation cycles of first and second row select circuits 2 and 4 can be set.

The semiconductor memory device further includes: a command decode circuit 8 decoding an external command CMD to generate an internal operation instructing signal; a refresh control circuit 10 for generating a self refresh mode setting signal SLREF and a refresh address select signal QSEL and generating refresh addresses QAD1 and QAD2 at prescribed time intervals in accordance with a self-refresh mode instructing signal SELF and a self-refresh end instructing signal from command decode circuit 8; a row-related control circuit 12 for controlling operations associated with row selection in memory cell array 1 according to a row activation instructing signal RACT from command decode circuit 8 and refresh activation signals REF1 and REF2 from refresh control circuit 10; an address input circuit 14 receiving external address signal EXAD; and an address select circuit (MUX) 16 selecting an address signal from address input circuit 14 and refresh addresses QAD1 and QAD2 in accordance with refresh address select signal QSEL from refresh control circuit 10 to generate an internal row address signal RAD to first and second row select circuits 2 and 4.

Command decode circuit 8 decodes external command CMD in synchronization with a clock signal, for example, to generate an operating mode instructing signal, in the form of a one-shot pulse signal, instructing an operating mode designated by command CMD.

Refresh control circuit 10 includes first refresh address generation circuit 20a and second refresh address generation circuit 20b that generate refresh addresses in different periods from each other. First refresh address generation circuit 20a generates refresh address signal QAD1 at a longer period of time, while second refresh address generation circuit 20b generates refresh address signal QAD2 in a short period of time. Address generation periods of first and second refresh address generation circuits 20a and 20b are made programmable.

By embedding refresh address generation circuits 20a and 20b for generating refresh addresses at different generation periods in refresh control circuit 10, a refresh address can be generated depending on a pause refresh characteristic (data holding characteristic) of each row in memory cell array 1, to execute refresh.

In row select circuits 2 and 4, which of refresh addresses QAD1 and QAD2 is used for selecting a corresponding row (word line) is programmed for each row, thereby enabling setting a refresh period according to a pause refresh characteristic (data holding characteristic) of each row. Especially, since a row inferior in pause refresh characteristic is smaller in number, a refresh cycle for the other memory cell rows good in pause refresh characteristic except a defective row is expanded, to be able to reduce the number of refresh times in a self-refresh mode, leading to decrease in current dissipation.

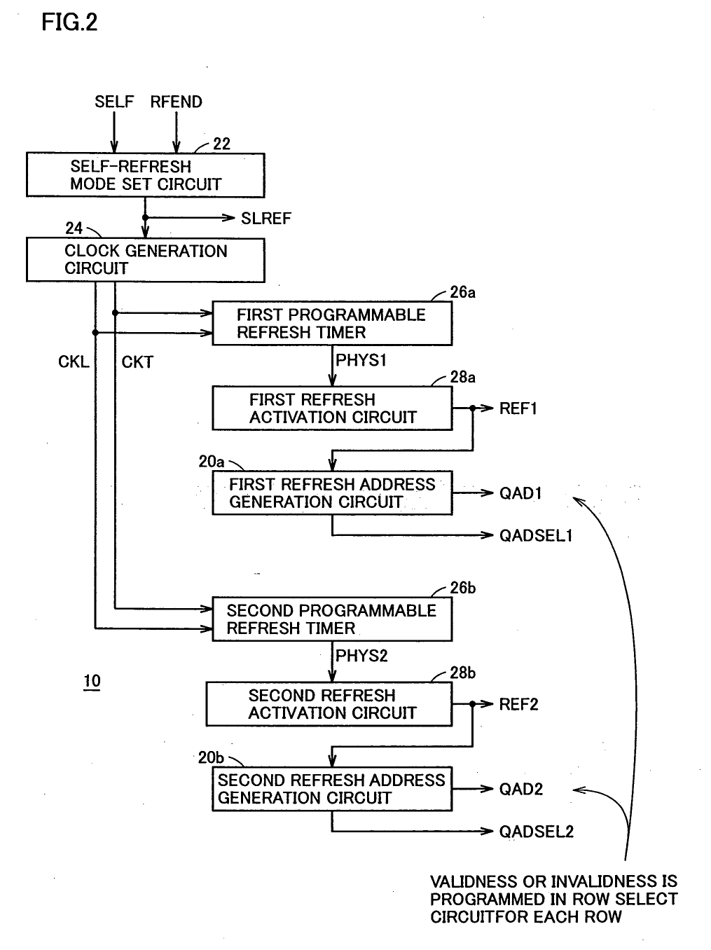

FIG. 2 is a diagram schematically showing a configuration of refresh control circuit 10 shown in FIG. 1. In FIG. 2, refresh control circuit 10 includes: a self-refresh mode set circuit 22 for generating self-refresh mode setting signal SLREF in accordance with self-refresh mode instructing signal SELF and a self-refresh end instructing signal RFEND from command decode circuit 8 shown in FIG. 1; a clock generation circuit 24 performing an oscillating operation in response to activation of self-refresh mode setting signal SLREF, to generate two-phase clock signals CKL and CKT; a first programmable refresh timer 26a counting clock signals CKT and CKL to issue a refresh request PHYS1 each time when a count thereof reaches a prescribed value; a first refresh activation circuit 28a activating refresh activation signal REF1 for a predetermined time period in response to activation of refresh request PHYS1; and a first refresh address generation circuit 20a for updating a refresh address QAD1 and generating a refresh address select signal QADSEL1 in accordance with refresh activation signal REF1.

Self-refresh mode set circuit 22 is formed of a set/reset flip flop, for example, and sets self-refresh mode setting signal SLREF in an active state at H level in response to activation of self-refresh mode instructing signal SELF while resetting self-refresh mode setting signal SLREF to an inactive state in accordance with activation of self-refresh end instructing signal RFEND.

Clock generation circuit 24 generates, when made active, two-phase clock signals CKT and CKL of a prescribed cycle. First programmable refresh timer 26a has a count thereof programmable and issues a refresh request PHYS1 each time when a count thereof reaches a programmed value. Refresh request PHYS1 is used for refreshing a memory cell excellent in pause refresh characteristic and a count of first programmable refresh timer 26a is set to an optimal refresh cycle depending on a good pause refresh characteristic. Accordingly, a refresh cycle for a memory cell with a good pause refresh characteristic is expanded, to reduce the number of times of refresh in a self-refresh mode, resulting in decreased average current dissipation.

First refresh activation circuit 28a activates refresh activation signal REF1 for a prescribed period when refresh request PHYS1 is issued, to activate a refresh operation on a memory cell excellent in pause refresh characteristic.

First refresh address generation circuit 20a updates refresh address QAD1 for each refresh operation and, therefore, an address for a memory cell excellent in pause refresh characteristic is updated in issuance periods of refresh request PHYS1.

Refresh control circuit 10 further includes: a second programmable refresh timer 26b for counting clock signals CKT and CKL from clock generation circuits 24 to issue a refresh request PHYS2 in a prescribed period; a second refresh activation circuit 28b for activating a refresh activation signal REF2 for a predetermined period of time in response to issuance of refresh request PHYS2; and a second refresh address generation circuit 20b for updating a refresh address QAD2 in accordance with refresh activation signal REF2 from second refresh activation circuit 28b, to generate a refresh address select signal QADSEL2.

Second programmable refresh timer 26b have also an issuance period of refresh request PHYS2 programmable. Therefore, refresh request PHYS2 is issued at an optimal refresh period for a memory cell having a defective pause characteristic detected in a test at a board level.

Operations of second refresh activation circuit 28b and second refresh address generation circuit 20b are the same as those of first refresh activation circuit 28a and first refresh address generation circuit 20a. Therefore, when refresh request PHYS2 is issued, refresh activation signal REF2 is activated to perform refresh on a memory cell with a defective pause refresh characteristic. An issuance period of refresh request PHYS2 is set shorter than that of refresh request PHYS1, to thereby make a refresh period for a memory cell with a defective pause refresh characteristic shorter for enabling data holding with certainty. A memory cell with a defective pause refresh characteristic is much smaller in number than memory cells of good pause refresh characteristic. A refresh cycle has been conventionally set in accordance with the memory cell with a defective pause refresh characteristic. Consequently, even if refresh cycle for a memory cell with a inferior pause refresh characteristic is made shorter, increase in number of refresh times can be suppressed as a whole, and an average current dissipation can be reduced.

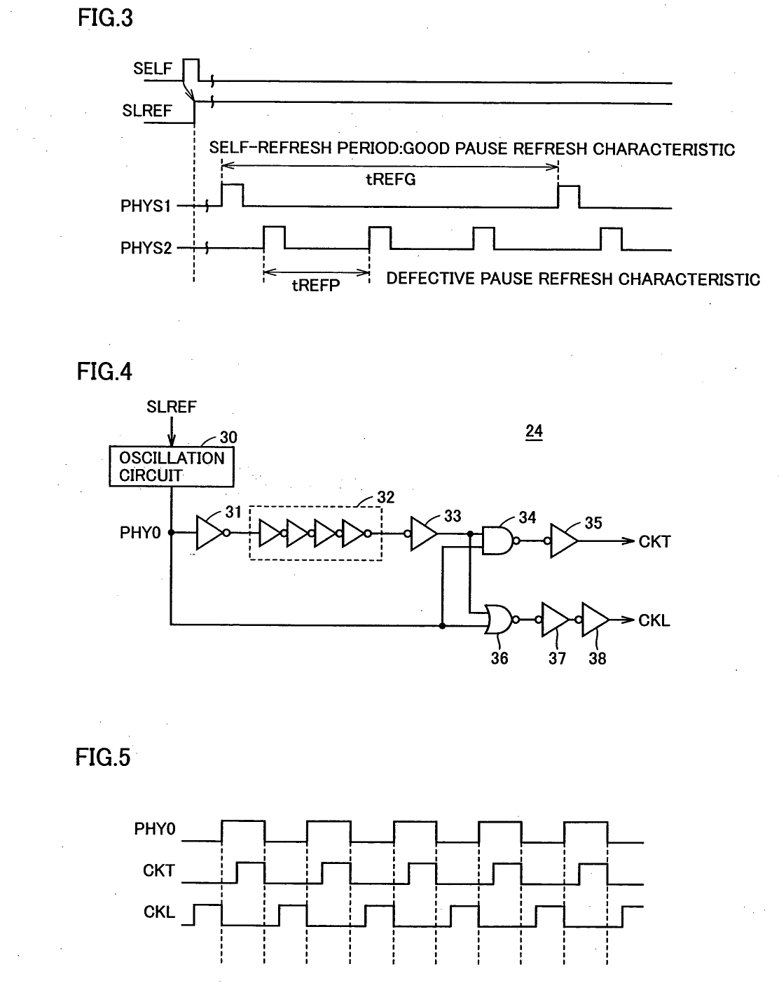

FIG. 3 is a timing chart representing an operation of refresh control circuit 10 shown in FIG. 2. Brief description will be given of operations of refresh control circuit 10 shown in FIG. 2 below with reference to FIG. 3.

When self-refresh instructing signal SELF is activated, self-refresh mode set circuit 22 shown in FIG. 2 sets self-refresh mode setting signal SLREF to an active state at H level. In response, clock generation circuit 24 is activated to generate two-phase clock signals CKL and CKT. Refresh requests PHYS1 and PHYS2 are issued at respective prescribed intervals in accordance with clock signals CKL and CKT.

Refresh request PHYS1 is issued for memory cells with good pause refresh characteristic at a refresh period tREFG, while refresh request PHYS2 is issued at a refresh period tREFP. Refresh period tREFG is longer than refresh period tREFP.

Even if the number of memory cells defective in pause refresh characteristic, or the number of defective pause refresh rows is sufficiently smaller than the number of word lines good in pause refresh characteristic, second refresh address generation circuit 20b updates an address count thereof in a shorter period adapted to defective characteristic, and a row defective in pause refresh characteristic can be refreshed at a period shorter than a row of good pause refresh characteristic, and thus memory cells of a defective pause characteristic can be repaired with certainty.

FIG. 4 is a diagram showing a configuration example of clock generation circuit 24 shown in FIG. 2. In FIG. 4, clock generation circuit 24 includes: an oscillation circuit 30 oscillating at a prescribed cycle in response to activation of self-refresh mode setting signal SLREF, to generate a refresh clock signal PHY0; an inverter 31 receiving refresh clock signal PHY0; a delay circuit 32 receiving an output signal of inverter 31; an inverter 33 receiving an output signal of delay circuit 32; a NAND circuit 34 receiving an output signal of inverter 33 and refresh clock signal PHY0; an inverter 35 inverting an output signal of NAND circuit 34 to generate clock signal CKT; a NOR circuit 36 receiving an output signal of inverter 33 and refresh clock signal PHY0; an inverter 37 receiving an output signal of NOR circuit 36; and an inverter 38 inverting an output signal of inverter 37 to generate clock signal CKL.

Delay circuit 32 is formed of an even number of stages of cascaded inverters and delays a received signal by a prescribed time. Here, it is noted that delay times in inverters 31 and 33 are neglected, as compared with that in delay circuit 32.

A rise delay circuit is constructed by inverters 31 and 33, delay circuit 32, NAND circuit 34 and inverter 35, while a fall delay circuit is constructed by inverters 31 and 33, delay circuit 32, NOR circuit 36 and inverter 37, and a polarity of a fall delayed signal is inverted.

FIG. 5 is a timing chart representing an operation of clock generation circuit 24 shown in FIG. 4. Description will be given of the operation of clock generation circuit 24 shown in FIG. 4 below with reference to FIG. 5.

When self-refresh mode setting signal SLREF is at L level, oscillation circuit 30 is in an inactive state, and refresh clock signal PHY0 is at L level. Therefore, in this state, clock signal CKT is at L level and clock signal CKL is at H level.

When self-refresh mode setting signal SLREF rises to H level, oscillation circuit 30 is activated to generate refresh clock signal PHY0 in a prescribed period. When a delay time that delay circuit 32 has elapses after refresh clock signal PHY0 rises to H level, NAND circuit 34 has both inputs turned into H level to raise clock signal CKT to H level. When refresh clock PHYS0 falls, an output signal of NAND circuit 34 rises to H level and clock signal CKT falls to L level.

An output signal of NOR circuit 36 falls to L level in response to rise of refresh clock signal PHYS0 and in response, clock signal CKL falls to L level. When refresh clock signal PHY0 falls, an output signal of NOR circuit 36 turns H level when a delay time that delay circuit 32 has elapses after a fall of refresh clock signal PHY0 and in response, clock signal CKL rises to H level.

Accordingly, a rise and fall of refresh clock signal PHY0 is delayed to generate clock signals CKT and CKL and to be able to generate two-phase, non-overlapping clock signals from refresh clock signal PHY0, which allows refresh times 26a and 26b (see FIG. 2) to correctly perform counting operations, to issue refresh requests in prescribed programmed periods.

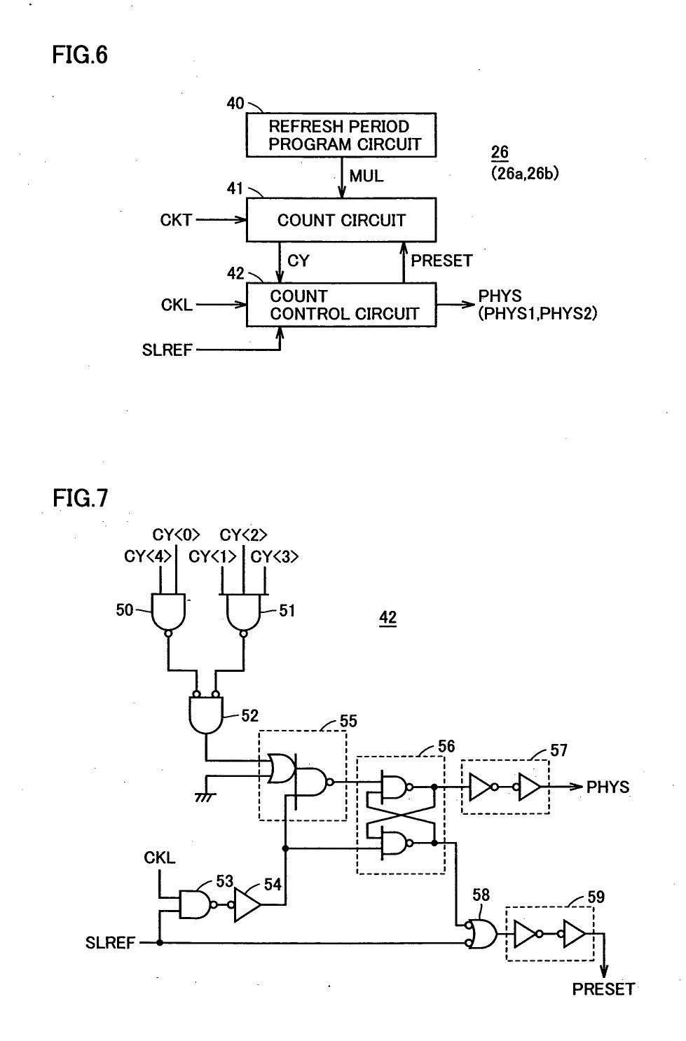

FIG. 6 is a diagram schematically showing a configuration of programmable refresh timers 26a and 26b shown in FIG. 2. Programmable refresh timers 26a and 26b have the same configuration, and there is shown in FIG. 26 a configuration of a programmable refresh timer 26 as a representative.

In FIG. 6, programmable refresh timer 26 includes: a refresh period program circuit 40 programming an issuance period of a refresh request; a count circuit 41 counting clock signal CKT to set all bits of a multi-bit output count CY to H level when a programmed value MUL of refresh period program circuit 40 and a count thereof coincide with each other; and a count control circuit 42 activated when self-refresh mode setting signal SLREF is activated, to issue refresh request PHYS in accordance with a count CY of count circuit 41 and clock signal CKL.

Count control circuit 42 sets a count preset signal PRESET to H level when all the bits of multi-bit output count CY turn H level. Count circuit 41 presets a refresh period programmed in refresh period program circuit 40 in accordance with activation of count preset signal PRESET. Count circuit 41 is an asynchronous count circuit and counts clock signal CKT with a lowest bit counter and the resultant count value is sequentially shifted to a higher bit side counter. Programmed value MUL and count value CY are each a multi-bit signal and the number of bits is set according to an available refresh period.

In refresh period program circuit 40, an appropriate refresh period is programmed, and refresh requests PHYS1 and PHS2 can be issued in desired refresh periods.

FIG. 7 is a diagram showing a configuration example of count control circuit 42 shown in FIG. 6. In FIG. 7, count control circuit 42 includes: a NAND gate 50 receiving count bits CY<0> and CY<4> of count circuit 41; a NAND gate 51 receiving count bits CY<1> to CY<3>; a NOR gate 52 receiving output signals of NAND gates 50 and 51; a NAND gate 53 receiving clock signal CKL and self-refresh mode setting signal SLREF; an inverter 54 receiving an output signal of NAND gate 53; a composite gate 55 receiving an output signal of inverter 54, an output signal of NOR gate 52 and ground voltage; a NAND type flip flop 56 set in response to an output signal of composite gate 55 and reset in response to an output signal of inverter 54; a buffer circuit 57 buffering an output signal of NAND type flip flop 56 to generate refresh request PHYS; a NAND gate 58 receiving one output of a set/reset flip flop 56 and self-refresh mode setting signal SLREF; and a buffer circuit 59 buffering an output signal of NAND gate 58 to generate the preset signal PRESET.

Composite gate 55 equivalently includes an OR gate receiving an output signal of NOR gate 52 and ground voltage, and a NAND gate receiving an output signal of the OR gate and an output signal of inverter 54.

When a count of count circuit 41 coincides with a programmed value MUL set in refresh period program circuit 40, count bits CY<4:0> all turn H level. As shown in FIG. 6, count circuit 41 counts clock signal CKT, and therefore count bits CY<4:0> are changed according to clock signal CKT.

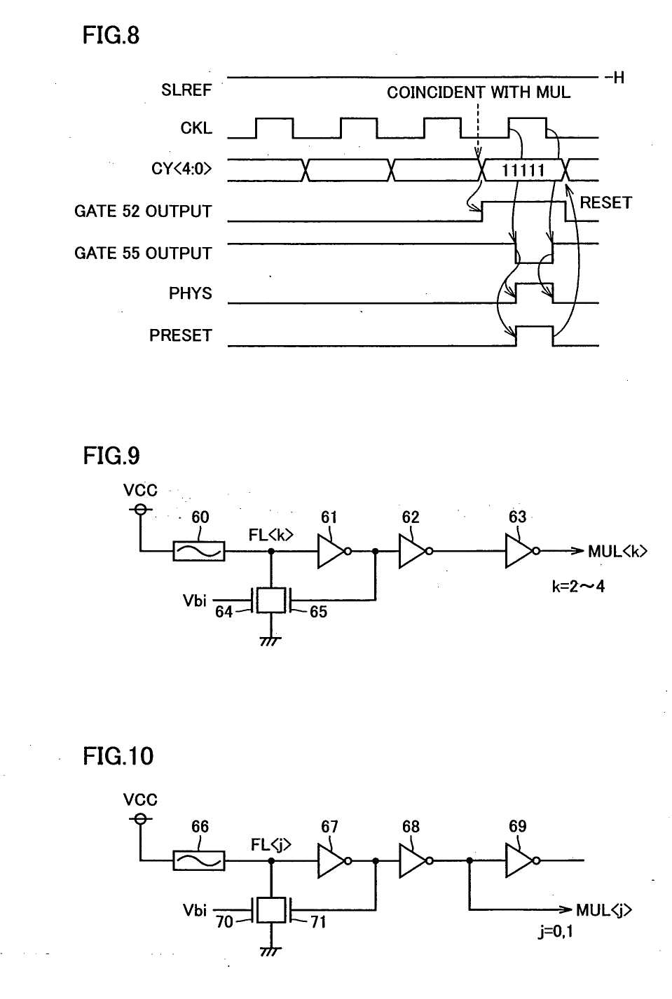

FIG. 8 is a timing chart representing an operation of count control circuit 42 shown in FIG. 7. Description will be given of the operation of count control circuit 42 shown in FIG. 7 below with reference to FIG. 8.

When self-refresh mode setting signal SLREF is at L level, an output signal of NAND gate 58 is at H level and preset signal PRESET is at H level. An output signal of NAND gate 53 is at H level, an output signal of inverter 54 is at L level, an output signal of composite gate 55 at H level, and flip flop 56 is in a reset state. Therefore, refresh request PHYS is fixed at L level.

In a self-refresh mode, self-refresh mode setting signal SLREF rises to H level to cause NAND gates 53 and 58 to each operate as an inverter. Since flip flop 56 is in a reset state, an output signal of NAND gate 58 attains L level to set preset signal PRESET to H level.

Count circuit 41 counts clock signal CKT and when the count value coincides with programmed value MUL, all the bits CY<4:0> attain L level to cause output signals of NAND gates 50 and 51 to turn H level. Accordingly, an output signal of NOR gate 52 attains H level. When clock signal CKL rises to H level, an output signal of NAND gate 53 attains L level and, in response, an output signal of inverter 54 attains H level. An output signal of composite gate 55 turns L level and flip-flop 56 is set and refresh request PHYS attains H level.

At this time, since a signal at L level from flip flop 56 is applied to NAND gate 58, preset signal PRESET also turns H level. A count of count circuit 41 shown in FIG. 6 is reset in accordance with preset signal PRESET to cause an output signal of gate 52 attain L level again. An H level period of refresh request PHYS and preset signal PRESET is determined by clock signal CKL.

Count control circuit 42 determines whether a count of count circuit 41 reaches programmed value MUL and issues refresh request PHYS on the basis of a result of determination and, in addition, initializes a count of count value 41. Refresh request PHYS is issued in accordance with clock signal CKL, and count circuit 41 shown in FIG. 6 performs a counting operation in accordance with clock signal CKT. Therefore, a count of count circuit 41 can be initialized correctly to start a counting operation by the count circuit 41 after issuance of refresh request PHYS.

FIG. 9 is a diagram showing a configuration of a fuse program circuit for a higher order bit, k, in refresh period program circuit 40 shown in FIG. 6. In FIG. 9 as well, program count value MUL is 5 bit data, and there is shown a configuration of a program circuit for highest 3 bits MUL<4:2>.

In FIG. 9, a fuse program circuit in refresh period program circuit 40 includes: a fuse element 60 coupled to a power supply node at one end; an inverter 61 receiving a signal FL<k> at the other end of fuse element 60; an inverter 62 receiving an output signal of an inverter 61; an inverter 63 inverting an output signal of inverter 62 to generate a count program bit MUL<k>; an N-channel MOS transistor (insulated gate field effect transistor) 65 connected between the input of inverter 61 and a ground node, and receiving an output signal of inverter 61 at a gate thereof; and an N-channel MOS transistor 64 connected between the input of inverter 61 and the ground node, and receiving a bias voltage Vbi at a gate thereof.

A bias voltage Vbi is a sufficiently low voltage and MOS transistor 64 has a sufficiently small current driving capability and works as a pull-down resistance.

In a configuration of the fuse program circuit shown in FIG. 9, fuse program signal FL<k> is at H level when fuse element 60 is in a non-blown state and an output signal of inverter 61 is at L level. Therefore, count program bit MUL<k> is at L level. When fuse element 60 is blown, fuse program signal FL<k> turns L level and an output signal of inverter 61 attains H level. Fuse program signal FL<k> is fixed at ground voltage level by inverter 61 and MOS transistor 65 and, in response, count program bit MUL<k> is set at H level.

FIG. 10 is a diagram showing a configuration of part of fuse program circuit for lower bits j=MUL<1:0> in refresh period program circuit 40 shown in FIG. 6. In FIG. 10, similarly to fuse program circuit shown in FIG. 9, a lower fuse program circuit includes: a fuse element 66 coupled to a power supply node; an inverter 67 inverting a fuse program signal FL<j> from a fuse element 66; an inverter 68 inverting an output signal of inverter 67 to generate count program bit MUL<j>; an inverter 69 receiving an output signal of inverter 68; an N-channel MOS transistor 71 fixing fuse program signal FL<j> to a ground voltage level when an output signal of inverter 67 is at H level; and an N-channel MOS transistor 70 pulling down an input of inverter 67 to ground voltage level in accordance with a bias voltage Vbi.

In the configuration of the fuse program circuit shown in FIG. 10, an output of inverter 69 is not used, but an output signal of inverter 68 at the preceding stage is utilized.

In a configuration of the fuse program circuit shown in FIG. 10, when fuse element 66 is in a non-blown state, fuse program signal FL<j> is at H level, an output of inverter 67 attains L level, and in response, count program bit MUL<j> attains H level. When fuse element 66 is blown, fuse program signal FL<j> is at L level and an output signal of inverter 67 attains H level. Therefore, in this state, count program bit MUL<j> is at L level.

A logic relation of a blowing and non-blowing of a fuse element is inverted between lower program count bits MUL<1:0> and higher program bits<4:2>. Such inverted relation is used for setting a minimum value of refresh period and for allowing the same circuit pattern to repeatedly used for each bit of count program bits MUL<4:0> to facilitate the circuit layout.

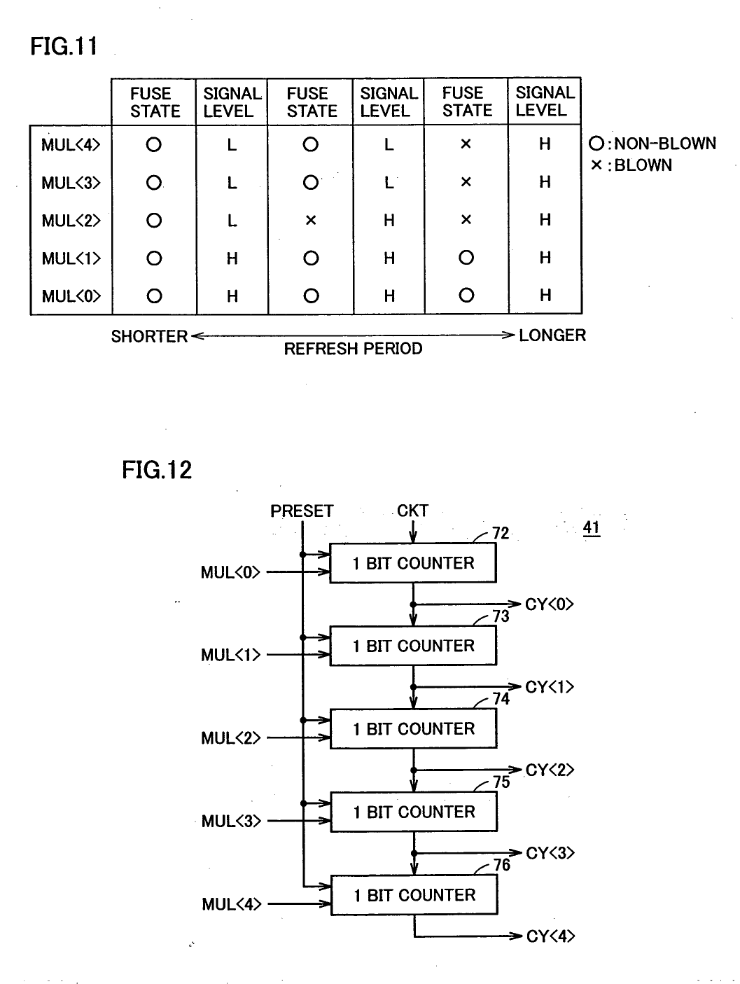

FIG. 11 illustrates a relationship among a count program bit, blowing/non-blowing of a fuse element and a refresh period. In FIG. 11, a blank circle mark indicates a non-blown state of a fuse element and an x mark indicates a blown state of a fuse element. When all the fuse elements are in a non-blown state, program count bits MUL<4:0> are (LLLHH) and indicate a count value of 4. When a fuse element for count bit MUL<2> is blown, count program bits<4:0> are (LLHHH) and indicate a count value of 8. If fuse elements for count bits MUL<2> to MUL<4> are all blown, count program bits MUL<4:0> become (HHHHH) and indicate a count value of 32.

The number of count of clock signal of a count circuit determining a refresh period is set by program count bits MUL<4:0>. Therefore, as the number of blown fuse elements increases, an issuance period of refresh requests is expanded. Accordingly, programming of a count of count circuit 41 allows setting of an issuance period of refresh requests according to a pause refresh characteristic.

It should be noted that in FIGS. 9 and 10, the number of program count bits is 5 bits, but the number of the count bits would be set according to the number of bits of counter circuit 41.

FIG. 12 is a diagram schematically showing a configuration of count circuit 41 shown in FIG. 6. In FIG. 12, count circuit 41 includes cascaded one-bit counters 72 to 76 of five stages. Preset signal PRESET is applied commonly to one-bit counters 72 to 76 and clock signal CKT is applied to one-bit counter 72 for the lowest bit. Count program bits MUL<0> to MUL<4> are applied to respective one-bit counters 72 to 76 and are preset in respective one-bit counters 72 to 76 in accordance with preset signal PRESET.

One-bit counters 72 to 76 output counter bits CY<0> to CY<4>, respectively. One-bit counter 72 alters a logic level of count bit CY<0> in response to activation (rise) of clock signal CKT. The other higher one-bit counters 73 to 76 alter logic levels of respective output bits in response to transition of the associated lower bits from H level to L level. One-bit counters 72 to 76 perform a counting down operation using count program bits MUL<0> to MUL<4> as initial count values and when count thereof coincide with count program value MUL, all of count bits CY<0> to CY<4> are set to H level.

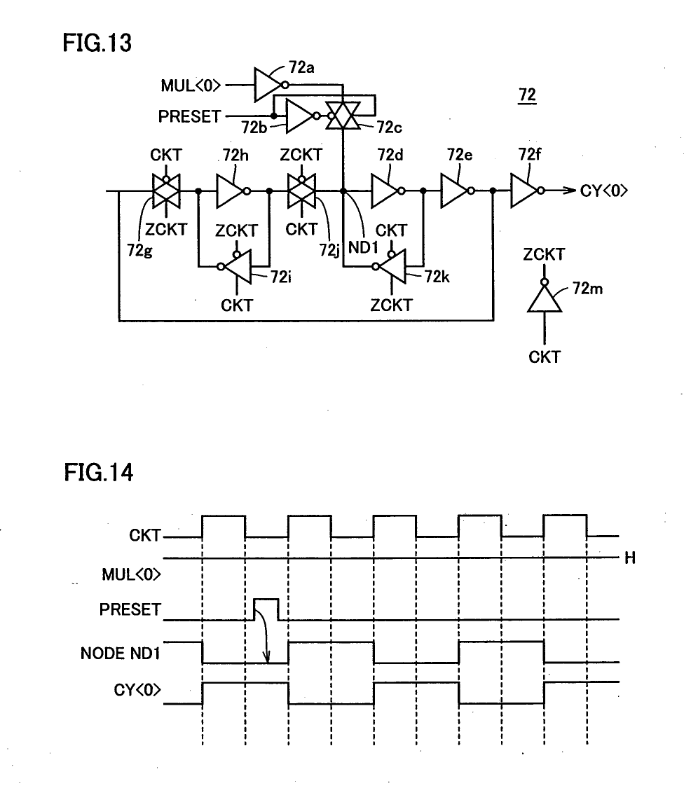

FIG. 13 is a diagram showing a configuration example of one-bit counter 72 shown in FIG. 12. In FIG. 13, one-bit counter 72 inverts clock signal CKT using inverter 72k, to generate a complementary clock signal ZCKT and to perform a counting operation according to complementary clock signals CKT and ZCKT.

In FIG. 13, one-bit counter 72 includes: an inverter 72a receiving count program bit MUL<0>; an inverter 72b receiving preset signal PRESET; a CMOS transmission gate 72c made conductive in accordance with preset signal PRESET and an output signal of inverter 72b to transmit, when conductive, an output signal of inverter 72a to a node ND1; an inverter 72d receiving an output signal node ND1; a tri-state inverter 72k activated when clock signal CKT is at L level, to transmit an output signal of inverter 72d to node ND1; an inverter 72e inverting an output signal of inverter 72d; and an inverter 72f inverting an output signal of inverter 72e to generate count bit CY<0>.

CMOS transmission gate 72c is made conductive when preset signal PRESET is at H level, to transmit an inverted value of count program bit MUL<0> from inverter 72a to node ND1.

One-bit counter 72 further includes: a CMOS transmission gate 72g made conductive when clock signal CKT is at L level, to transmit, when conductive, an output signal of inverter 72e; an inverter 72h receiving a signal passing through CMOS transmission gate 72g; a tri-state inverter 72i activated when clock signal CKT is at H level, to transmit an output signal of inverter 72h to the input of inverter 72h; and a CMOS transmission gate 72j made conductive when clock signal CKT is at H level, to transmit, when conductive, an output signal of inverter 72h to node ND1.

One-bit counter 72, therefore, sequentially inverts and transfers internally the count bit in accordance with clock signal CKT, to update a bit value of count bit CY<0>.

FIG. 14 is a timing chart representing an operation of the one-bit counter shown in FIG. 13. Description will be given of operations in one-bit counter 72 shown in FIG. 13 below with reference to FIG. 14.

Count program bit MUL<0> is at H level. When preset signal PRESET attains H level, CMOS transmission gate 72c is made conductive to preset node ND1 to L level.

Inverter 72d and tri-state inverter 72k form a latch circuit when clock signal CKT is at L level, and inverter 72h and tri-state inverter 72i form a latch circuit when clock signal CKT is at H level. CMOS transmission gate 72g is made conductive when clock signal CKT is at L level and CMOS transmission gate 72j is made conductive when clock signal CKT is at H level.

Accordingly, an output signal of inverter 72e is transmitted to node ND1 when one clock cycle of clock signal CKT elapses. Specifically, node ND1 has a signal potential changed in logic level at each rise of clock signal CKT and, in response, count bit CY<0> also has a logic level thereof changed in response to a rise of clock signal CKT. A bit value of count bit CY<0> can be set according to the number of clock signals CKT.

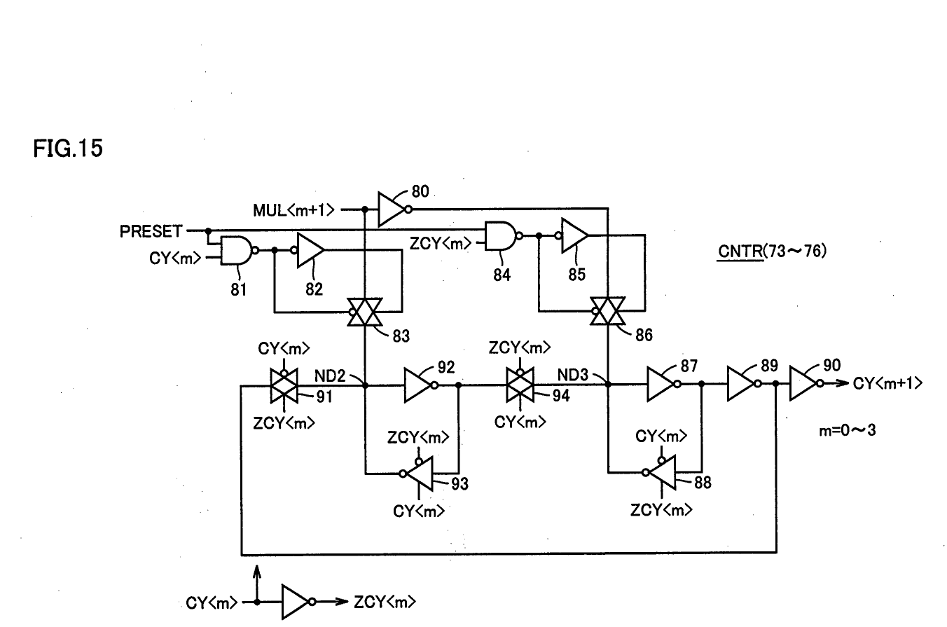

FIG. 15 is a diagram showing a configuration of one-bit counters 73 to 76 shown in FIG. 12. Since one-bit counters 73 to 76 have the same configuration with each other, in FIG. 15, there is shown one-bit counter CNTR as a representative.

In FIG. 15, one-bit counter CNTR includes: an inverter 80 receiving count program bit MUL<m+1>; a NAND gate 81 receiving preset signal PRESET and count bit CY<m>; an inverter 82 receiving an output signal of NAND gate 81; a CMOS transmission gate 83 selectively made conductive according to an output signal of NAND gate 81 and an output signal of inverter 82, to transmit count program bit MUL<m+1> to a node ND2; a NAND gate 84 receiving preset signal PRESET and complementary count bit ZCY<m>; an inverter 85 receiving an output signal of NAND gate 84; and a CMOS transmission gate 86 selectively made conductive in accordance with an output signal of NAND gate 84 and an output signal of inverter 85, to transmit an output signal of inverter 80 to a node ND3. Complementary count bit ZCY<m> is generated, using an inverter, from count bit CY<m>.

One-bit counter CNTR further includes: an inverter 87 inverting a signal on node ND3; a tri-state inverter 88 activated when count bit CY<m> is at L level, to transmit a output signal of inverter 87 to node ND3; an inverter 89 receiving an-output signal of inverter 87; an inverter 90 inverting an output signal of inverter 89 to generate count bit CY<m+1>; a CMOS transmission gate 91 made conductive when count bit CY<m> is at L level, to transmit, when conductive, an output signal of inverter 89 to node ND2; an inverter 92 inverting a signal on node ND2; a CMOS transmission gate 94 made conductive when count bit CY<m> is H level, to transmit, when made conductive, an output signal of inverter 92 to node ND3; and a tri-state inverter 93 activated when count bit CY<m> is at H level, to transmit, when activated, an output signal of inverter 92 to node ND2.

Tri-state inverters 88 and 93, together with inverters 87 and 92, constitute a latch circuit when active, respectively. CMOS transmission gates 91 and 94 are made conductive complementarily to each other. Therefore, a signal on node ND3 is transmitted to node ND2 with a delay of one cycle of count bit CY<m>. One-bit counter CNTR alters a logic level of count bit CY<m+1> at each rise of adjacent lower count bit CY<m>.

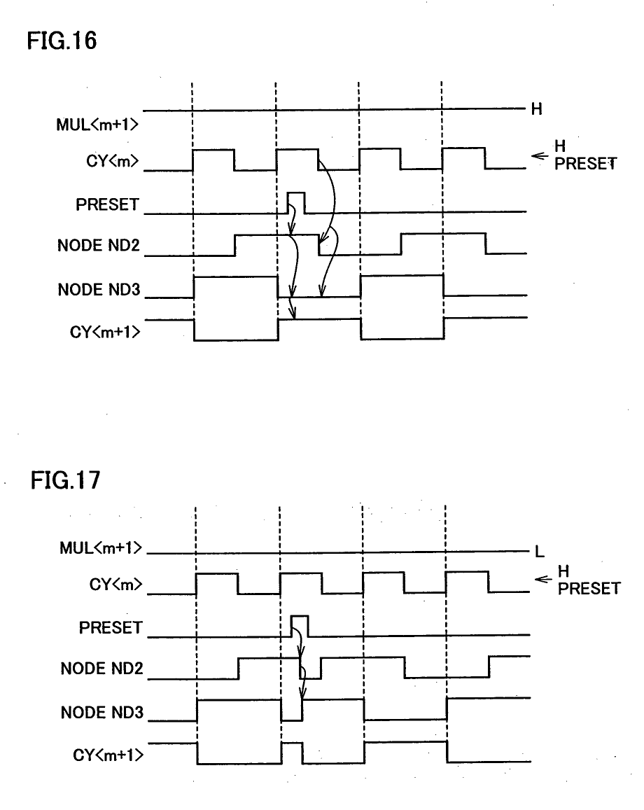

FIGS. 16 and 17 are timing charts representing operations of the one-bit counter CNTR shown in FIG. 15. Description will be given of operations in one-bit counter CNTR shown in FIG. 15 below with reference to FIGS. 16 and 17.

First, referring to FIG. 16, description will be given of operations in a case where count program bit MUL<m+1> is set to H level. It is noted that in the following description, a case is considered where when a lower one-bit counter is preset, count bit CY<m> is preset to H level.

Now, a state is considered where node ND2 is at L level. In this state, when count bit CY<m> rises to H level, CMOS transmission gate 94 is made conductive, the signal at node ND3 turns H level and, in response, count bit CY<m+1> falls to L level. Count bit CY<m> is at H level and therefore, CMOS transmission gate 91 is in a non-conductive state.

When count bit CY<m> falls to L level, CMOS transmission gate 91 turns conductive to cause node ND2 to attain H level in accordance with count bit CY<m+1> at H level. Then, when count bit CY<m> rises to H level, CMOS transmission gate is made conductive, node ND3 attains L level by tri-state inverter 92 and, in response, count bit CY<m+1> rises to H level.

In this state, when all of count bits CY<4:0> are at H level, preset signal PRESET is activated. Since count bit CY<m> is preset to H level, an output signal of NAND gate 81 attains L level, CMOS transmission gate 83 turns conductive and node ND2 is preset to H level according to count program bit MUL<m+1>. Since CMOS transmission gate 94 is conductive at this time, node ND3 is preset to L level by inverter 92 and, in response, count bit CY<m+1> is also preset to H level.

In this state, when count bit CY<m> falls to L level, CMOS transmission gate 91 turns conductive, node ND2 is set to H level according to L level at node ND3. At this time, CMOS transmission gate 94 is in a non-conductive state and count bit CY<m+1> is not altered.

Subsequently, when count bit CY<m> rises to H level, CMOS transmission 94 is made conductive, a potential at node ND3 is driven to H level and, in response, count bit CY<m+1> attains L level. Thereafter, each time when count bit CY<m> rises, a logic level of count bit CY<m+1> alters.

Then, referring to FIG. 17, description will be given of operations in a case where count program bit MUL<m+1> is set to L level. Operations before preset signal PRESET rises to H level are the same as those shown in the timing chart of FIG. 16. When all of the count bits attain H level and preset signal PRESET rises to H level, count program bit MUL<m+1> is transmitted to node ND2 through CMOS transmission gate 83 to cause the signal at node ND2 to fall from H level to L level. At this time, CMOS transmission gate 94 is in a conductive state, in response, the signal at node ND3 attains H level, and count bit CY<m+1> is preset to L level.

When count bit CY<m> falls to L level, CMOS transmission gate 91 is made conductive and node ND2 attains H level. CMOS transmission gate 94 is made conductive in response to the next rise of count bit CY<m>, a potential at node ND3 is driven to L level and count bit CY<m+1> rises to H level. Thereafter, each time when count bit CY<m> attains H level, a logic level of count CY<m+1> is altered.

In a case where count bit CY<m> is preset to L level, CMOS transmission gate 86 is made conductive by NAND gate 84 according to preset signal PRESET and an inverted value of count program bit MUL<m+1> is transmitted to node ND3. When count bit CY<m> is preset to L level and count bit CY<m+1> is also preset to L level, count bit CY<m+1> rises to H level in response to a rise of count bit CY<m>.

Accordingly, a counting operation can be performed in one-bit counters for which bits in program count bits MUL<4:0> are set to H level.

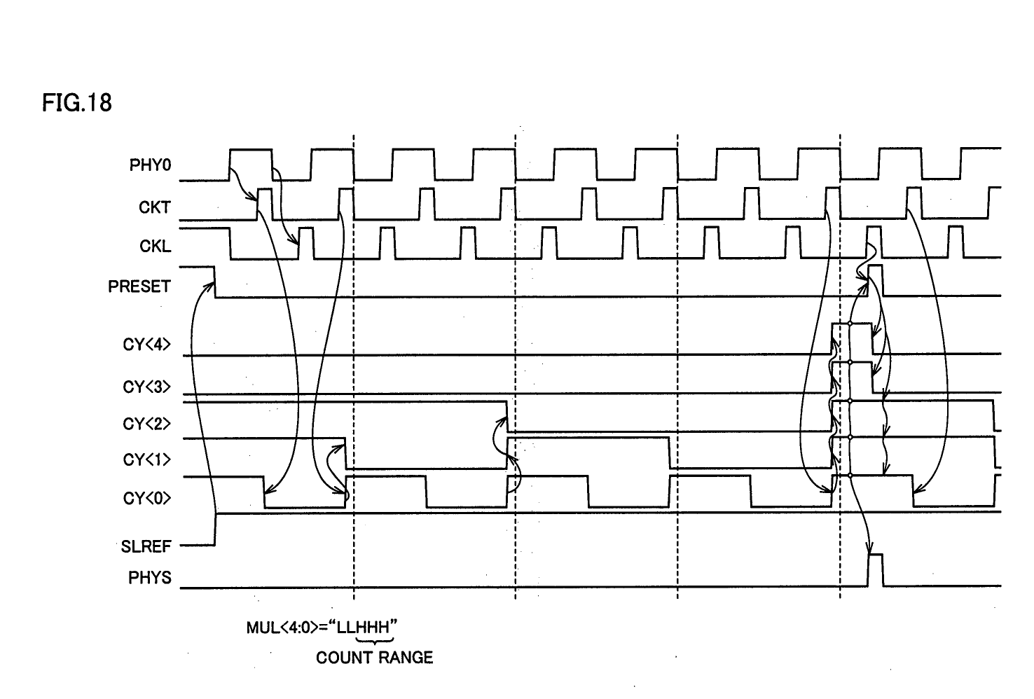

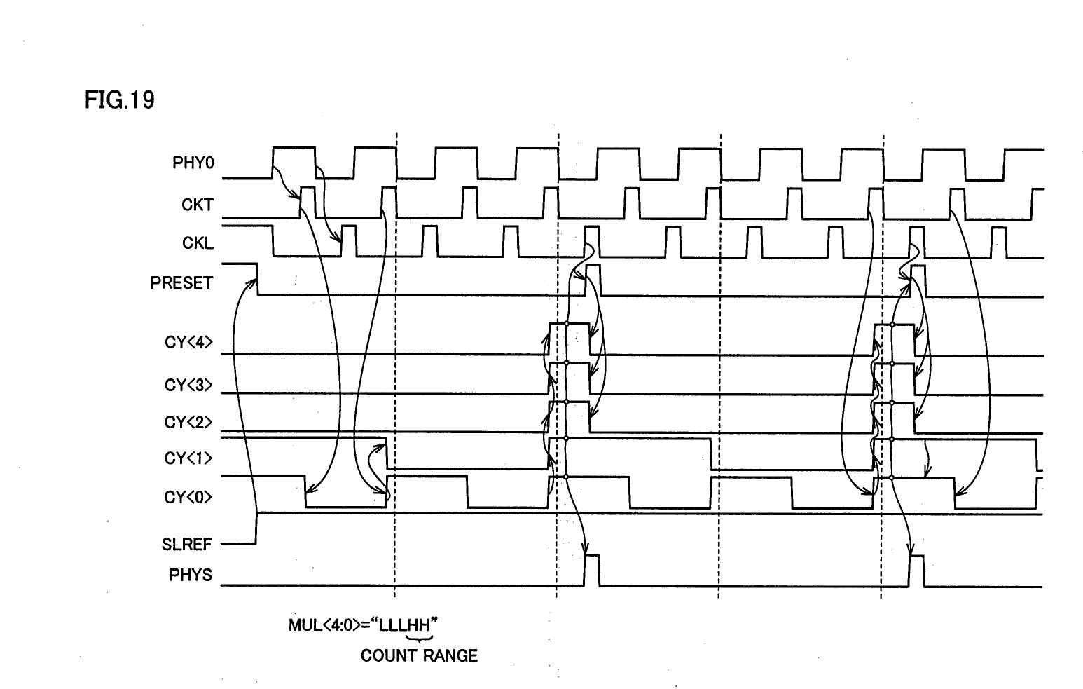

FIGS. 18 and 19 are timing charts representing specifically a counting operation in a case where a 5-bit counter is formed of one-bit counters shown in FIGS. 13 and 15. In FIG. 18, there are shown operations in a case where count program bits MUL<4:0> are set “LLHHH.” In this case, count bits CY<2:0> are all set to H level and count bits CY<4:3> are each set to L level. In a self-refresh counting, self-refresh mode setting signal SLREF rises to H level and preset signal PRESET attains L level. Bits of count circuits are preset when preset signal PRESET is at H level.

In a self-refresh mode, two-phase clock signals CKT and CKL are generated in accordance with refresh clock signal PHY0. Count circuit 41 performs a counting operation in accordance with clock signal CKT. One-bit counter 72 shown in FIG. 12 updates a logic level of count bit CY<0> in accordance with clock signal CKT. Subsequently, higher one-bit counters 73 and 74 updates logic levels of outputs thereof in accordance with output count bits CY<0> and CY<1> of associated lower one-bit counters 72 and 73.

Therefore, when clock signal CKT is counted eight times, bits CY<2:0> all attain H level. When count bit CY<2> rises from L level to H level, count bit CY<3> rises from L level to H level. Count bit<4> also rises to H level in accordance with a rise of count bit CY<3>. Therefore, count bits CY<4:0> all attain H level, refresh request PHYS is issued from count control circuit 42 shown in FIG. 7 in synchronization with clock signal CKL and, in addition, preset signal PRESET attains H level. Count bits CY<4:0> are again set to an initial state according to preset signal PRESET.

That is, count circuit 41 performs a counting down operation from an initially set value and issues refresh request PHYSS and preset signal PRESET when the count reaches a programmed count value.

A program count value can be counted while setting a region, as a count range, except bits set to L level in program count bits MUL<4:0>.

FIG. 19 is a timing chart representing another example of an operation of 5-bit counter circuit 41 using one-bit counters shown in FIGS. 13 and 15. In a sequence of operations shown in FIG. 19, count program bits MUL<4:0> are set to “LLLHH.” Therefore, in a self-refresh mode, when self-refresh mode setting signal SLREF rises to H level and preset signal PRESET attains L level, count bits CY<4:0> all attain H level when the clock signal is counted four times since a count range is a 2 bit counter region, to allow issuance of refresh request PHYS and preset signal PRESET.

Accordingly, in count circuit 41, by utilizing an asynchronous count circuit of updating a logic level of a higher output bit count in response to a rise of a lower bit, a desired count value can be programmed, and a refresh request can be issued at a desired period.

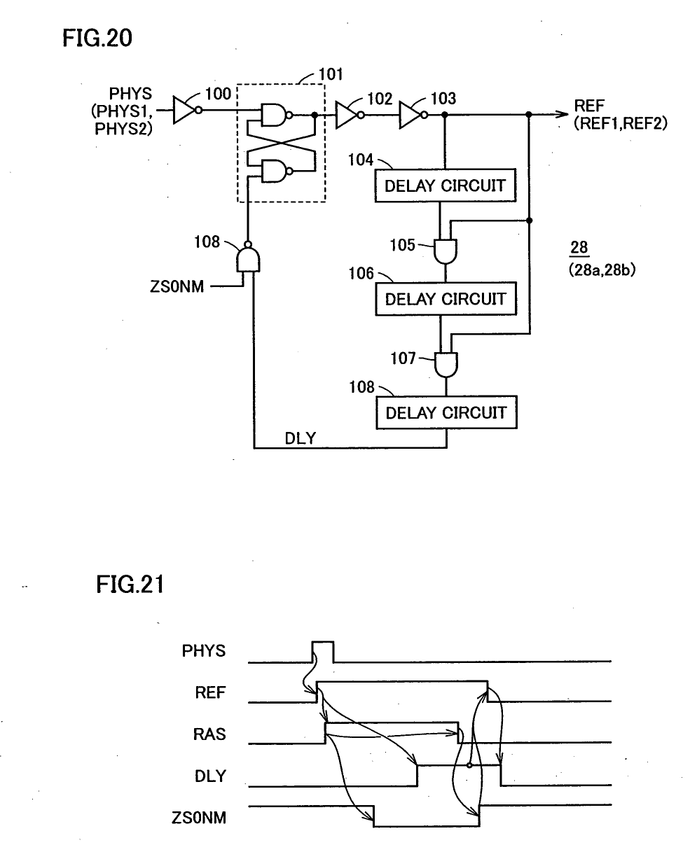

FIG. 20 is a diagram showing a configuration example of refresh activation circuit 28a or 28b shown in FIG. 2. First and second refresh activation circuits 28a and 28b have the same configuration with each other, and therefore, in FIG. 20, there is shown a configuration of refresh activation circuit 28 for generically showing refresh activation circuits 28a and 28b.

Refresh activation circuit 28 includes: an inverter 100 receiving refresh request PHYS; a set/reset flip flop 101 set in response to an output signal of inverter 100; an inverter 102 receiving an output signal of set/reset flip flop 101; an inverter 103 receiving an output signal of inverter 102 to generate refresh activation signal REF; a delay circuit 104 delaying an output signal of inverter 103 by a prescribed time; an AND circuit 105 receiving an output signal of delay circuit 104 and refresh activation circuit REF; a delay circuit 106 delaying an output signal of AND circuit 105 by a prescribed time; an AND circuit 107 receiving an output signal of delay circuit 106 and refresh activation signal REF; a delay circuit 108 delaying an output signal of AND circuit 107 by a prescribed time; and an inverter 108 inverting an output signal DLY of delay circuit 108 to reset the set/reset flip flop 101.

In refresh activation circuit 28, an active period of refresh activation signal REF is determined by delay times of delay circuits 104, 106 and 108.

FIG. 21 is a signal waveform diagram representing an operation of refresh activation circuit 28 shown in FIG. 20. Description will be given of the operation of refresh activation circuit 28 shown in FIG. 20 below with reference to FIG. 21.

When refresh request PHYS is issued, an output signal of inverter 100 attains L level, set/reset flip flop 101 is set and refresh activation signal REF attains H level.

In a row-related control circuit described later, row address strobe signal RAS driving row-related circuitry to an active state is driven to an active state in accordance with refresh activation signal REF. Row selection is performed in accordance with row address strobe signal RAS to perform refresh of a selected memory cell. When a prescribed time elapses from activation of refresh activation signal REF, output signal DLY of delay circuit 108 attains H level.

On the other hand, when a prescribed time elapses after activation of row address strove signal RAS, a sense amplifier activation signal ZS0NM is activated to perform a sensing operation. Then, when a prescribed time elapses, row address strobe signal RAS falls to L level in a self-refresh mode and in response, sense amplifier activation signal ZS0NM turns into H level of an inactive state. By deactivating sense amplifier activation signal ZS0NM, an output signal of NAND gate 108 attains L level, set/reset flip flop 101 is reset and refresh activation signal REF is deactivated. When a prescribed time elapses after deactivation of refresh activation signal REF, output signal DLY of delay circuit 108 also turns L level.

Accordingly, a refresh period of time during which refresh of data of memory cells is actually performed is secured by refresh activation signal REF, and a refresh operation is executed by row address strobe signal RAS during the period of time. Accordingly, it is prevented from occurring that another command is supplied to drive an internal operation to an erroneous state during the refresh period of time. In addition, even when refresh requests PHYS1 and PHYS2 are issued concurrently to each other, it is prevented from occurring that refresh operations are performed in an overlapping way.

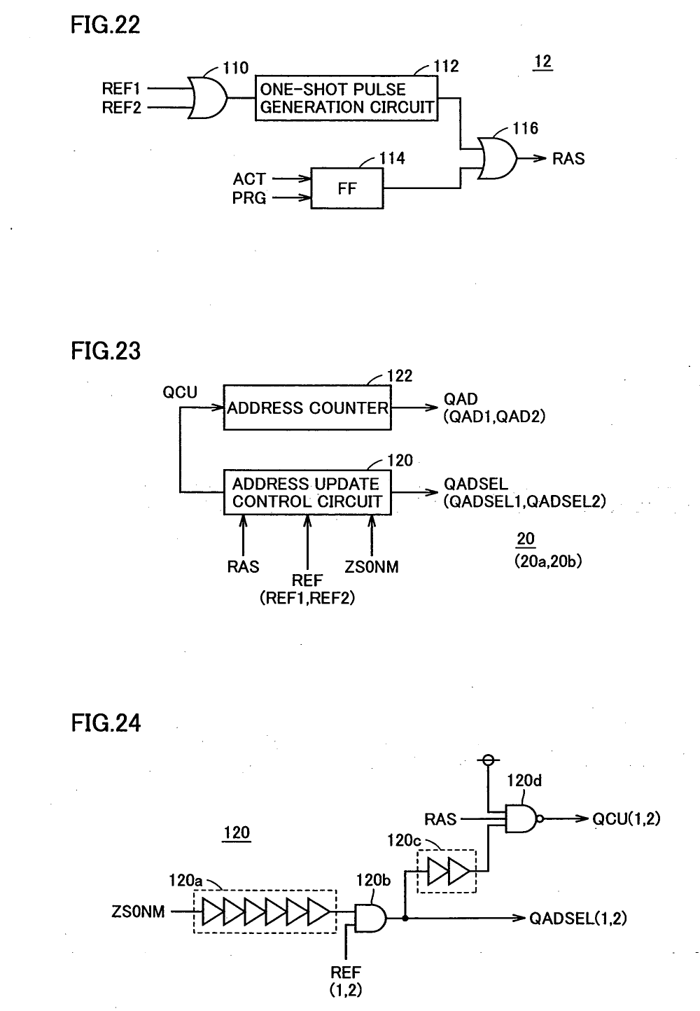

FIG. 22 is a diagram showing a configuration example of a section of generating row address strobe signal RAS included in row-related control circuit 12 shown in FIG. 1. In FIG. 22, the row address strobe signal generating section includes: an OR gate 110 receiving refresh activation signals REF1 and REF2; a one-shot pulse generation circuit 112 generating a one-shot pulse having a prescribed width in response to a rise of an output signal of OR gate 110; flip flop (FF) 114 set in response to array activation instructing signal ACT (corresponding to row activation instructing signal RACT) from command decode circuit 8 shown in FIG. 1, and reset in response to precharge operation instructing signal PRG; and an OR circuit 116 receiving an output signal of one-shot pulse generation circuit 112 and an output signal of flip flop 114 to generate row address strobe signal RAS.

Array activation instructing signal ACT is activated when array active command is applied and a row selection is instructed. Array activation instructing signal ACT corresponds to row activation instructing signal RACT shown in FIG. 1. Here, a symbol ACT generally used for an active command is employed in order to show a combination with precharge command PRG.

As shown in FIG. 22, in a self-refresh mode period, an active period of row address strobe signal RAS is determined by a pulse generated by one-shot pulse generation circuit 112, while in a normal operation mode, its active period is determined by a period from application of an active command till application of precharge command.

FIG. 23 is a diagram schematically showing a configuration of refresh address generation circuits 20a and 20b shown in FIG. 2. Since refresh address generation circuits 20a and 20b have the same configuration, in FIG. 23, there is shown refresh address generation circuit 20 as a representative thereof.

In FIG. 23, refresh address generation circuit 20 includes: an address update control circuit 120 generating a count update signal QCU and a refresh address select signal QADSEL in accordance with row address strobe signal RAS, refresh activation signal REF (REF1 or REF2) and sense amplifier activation signal ZS0NM; and an address counter 122 updating a count thereof in accordance with update instructing signal QCU from address update control circuit 120, to generate refresh address QAD (QAD1 or QAD2).

Row address strobe signal RAS and sense amplifier activation signal ZS0NM are generated commonly for refresh activation signals REF1 and REF2. Row address strobe signal RAS and sense amplifier activation signal ZS0NM are selectively modified in accordance with refresh activation signal REF to update a refresh address in address generating circuit having refresh performed.

FIG. 24 is a diagram showing a configuration example of address update control circuit 120 shown in FIG. 23. In FIG. 24, address update control circuit 120 includes: a delay circuit 120a delaying sense amplifier activation signal ZS0NM by a prescribed time; an AND circuit 120b receiving an output signal of delay circuit 120a and refresh activation signal REF (REF1 or REF2); a delay circuit 120c delaying an output signal of AND gate 120b; and a NAND gate 120d receiving an output signal of delay circuit 120c, row address strobe signal RAS and power supply voltage to generate count update signal QCU (QCU1, or QCU2). Refresh address select signals QADSEL (QADSEL1, or QADSEL2) are generated from AND gate 120b.

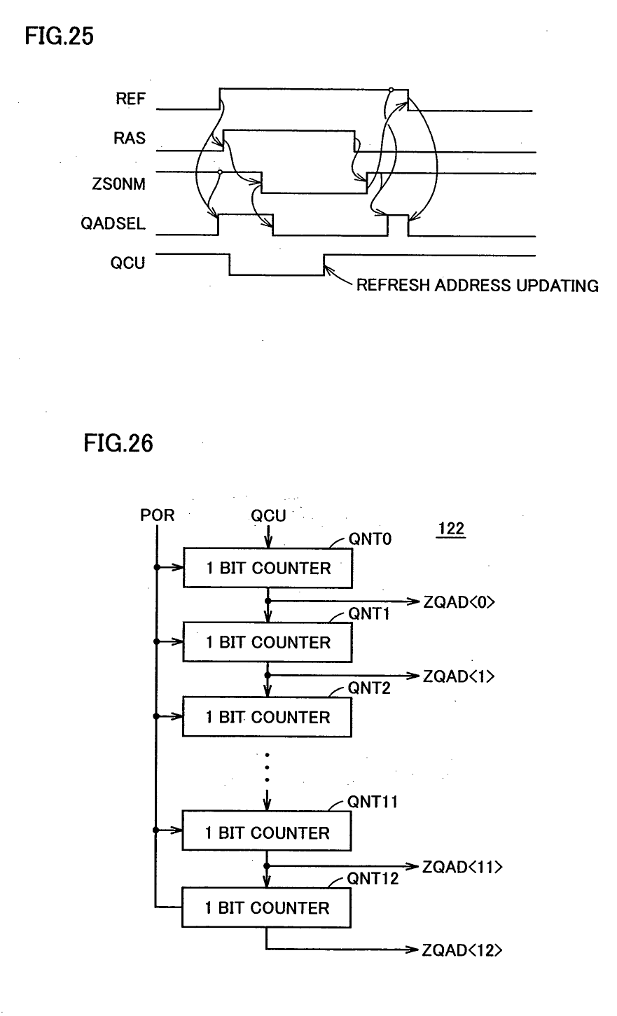

FIG. 25 is a signal waveform diagram representing an operation of address update control circuit 120 shown in FIG. 24. Description will be given of operations in address update control circuit 120 shown in FIG. 24 with reference to FIG. 25. When a refresh operation is performed, refresh activation signal REF is activated in response to the refresh request. At this time, sense amplifier activation signal ZS0NM is still at H level, in response an output signal of AND circuit 120b attains H level and refresh address select signal QADSEL turns H level. A refresh address is selected according to refresh address select signal QADSEL. Since sense amplifier activation signal ZS0NM is at H level and row address strobe signal RAS attains H level upon start of a refresh operation, address update signal QCU from NAND gate 120d attains L level when a delay time of delay circuit 120c elapses after activation of refresh address select signal QADSEL.

When a prescribed period elapses after row address strobe signal RAS attains H level, sense amplifier activation signal ZS0NM is activated and there are performed sensing and amplification and rewriting of data in memory cells on a refresh row. Refresh address select signal QADSEL from AND gate 120b attains L level in response to activation of sense amplifier activation signal ZS0NM after a delay time of delay circuit 120a elapses.

Address update signal QCU from NAND gate 120d attains H level and refresh address is updated after a delay time that delay circuit 120c has elapses from a fall of refresh address select signal QADSEL.

When a refresh period is completed, row address strobe signal RAS attains L level and subsequently, sense amplifier activation signal ZS0NM turns H level. Address update signal QCU from AND gate 120d attains L level in response to a fall of row address strobe signal RAS and a refresh address is updated in address count 122 shown in FIG. 23.

When sense amplifier activation signal ZS0NM attains H level, refresh address select signal QADSEL attains H level and a refresh address newly updated is selected during a period when refresh activation signal REF is at H level. At this time, row address strobe signal RAS is in an inactive state and the next refresh address is selected in a precharge state in order to prepare for the next refresh operation cycle.

By activating refresh address select signal QADSEL before and after a refresh operation, a new refresh address is available when a refresh operation starts, so that the refresh address can be driven to a definite state at a faster timing with certainty to drive a block select signal described later to a definite state at a faster timing.

It is noted that in the configuration of address update control circuit 120 shown in FIG. 24, refresh address select signal QADSEL is activated before and after a refresh operation. A period during which refresh address select signal QADSEL is at H level may be on the same order as an active period of row address strobe signal RAS. In a refresh operation, refresh address can be selected to select a refresh row with certainty. By appropriately setting a delay time of delay circuit 120a, a period during which refresh address select signal QADSEL is at H level can be set to a suitable period of time.

FIG. 26 is a diagram schematically showing a configuration of address counter 122 shown in FIG. 23. Address counter 122 generates 13-bit refresh address signal ZQAD<12:0> as refresh address QAD. In FIG. 26, address counter 122 includes cascaded one-bit counters QNT0 to QNT12, each of which alters a logic level of its output bit in response to a change (a rise) in each respective lower bit.

Address update signal QCU is applied to the lowest one-bit counter QNT0. A power-on detecting (reset) signal POR is applied commonly to one-bit counters QNT0 to QNT12 and a count value of address counter 122 is reset to an initial value when power is turned on.

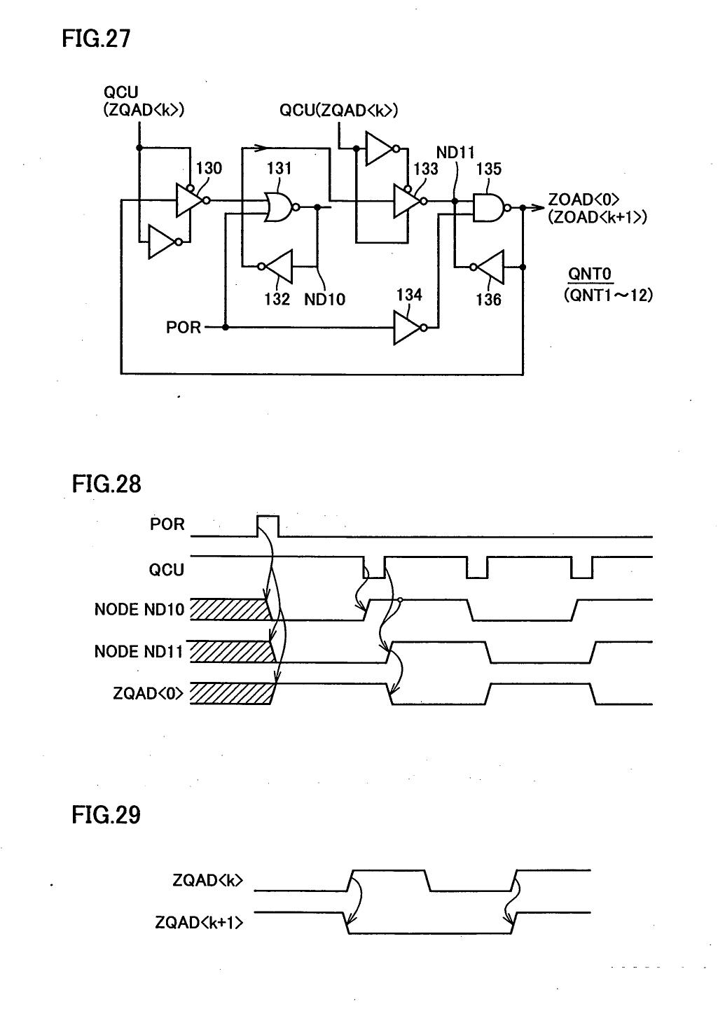

FIG. 27 is a diagram showing an example of a specific configuration of one-bit counter QNT0 to QNT12 shown in FIG. 26. In FIG. 27, there is shown a configuration of the lowest one-bit counter QNT0. As for the other one-bit counters QNT1 to QNT12, the same configuration is employed, in which an output bit alters in response to a rise of an address bit of the lower order.

In FIG. 27, one-bit counter QNT0 includes: a tri-state inverter 130 activated when refresh address update signal is at L level, for inverting a complementary refresh address bit ZQAD<0>; an NOR gate 131 receiving an output signal of tri-state inverter 130 at a first input, and receiving power-on detecting signal POR at a second input; an inverter 132 inverting an output signal of NOR gate 131 for transmission to the first input of NOR gate 131; a tri-state inverter 133 activated when refresh address update signal QCU is at H level, to invert an output signal of inverter 132 for transmission to node ND11; an inverter 134 receiving power-on detecting signal POR; a NAND gate 135 receiving a signal on node ND11 and an output signal of inverter 134 to generate complementary address bit ZQAD<0>; and an inverter 136 inverting an output signal of NAND gate 135 and transmitting the inverted signal to node ND11.

Address bit QAD<0> is generated by inverting address bit ZQAD<0>.

FIG. 28 is a timing chart representing an operation of one-bit counter QNT0 shown in FIG. 27. Description will be given of operations in one-bit counter QNT0 shown in FIG. 27 below with reference to FIG. 28.

When power is turned on and a power supply voltage is stabilized, power-on detecting (reset) signal POR is generated in the form of a one-shot pulse. An output node ND10 of NOR gate 131 is initialized to L level in accordance with power-on detecting signal POR and address bit ZQAD<0> outputted by NAND gate 135 is initialized to H level. When power-on detecting signal POR falls to L level, node ND10 is maintained at L level since NOR gate 131 and inverter 132 form a latch circuit. Likewise, address bit ZQAD<0> is maintained at H level since NAND gate 135 and inverter 136 form a latch circuit. In this state, address bit QAD<0> is at L level. Accordingly, all the bits in refresh address QAD are “0” at an initial stage.

When refresh address update signal QCU falls to L level after a refresh operation is performed, tri-state inverter 130 is activated to invert address bit ZQAD<0> at H level for application to the first input of NOR gate 131. In response, node ND10 attains H level and an output signal of inverter 132 attains L level. Tri-state inverter 133 is in an output high impedance state and refresh address bit ZQAD<0> maintains the initial value while refresh address update signal QCU is at H level.

When refresh address update signal QCU rises to H level, tri-state inverter 133 is activated to invert a signal at H level from inverter 132, a voltage level at node ND11 attains L level and in response, address bit ZQAD<0> attains L level. Tri-state inverter 130 is in an output high impedance state and node ND10 maintains H level while refresh address update signal QCU is at H level.

Thereafter, each time when refresh address update signal QCU falls to L level, a logic level of node ND10 alters, the level change at node N10 is transmitted to node ND11 in response to a rise of refresh address update signal QCU and in response, a logic level of address bit ZQAD<0> is altered.

Accordingly, each time when refresh is performed, updating of a refresh address is performed. As shown in FIG. 25, after a refresh operation is completed, refresh address update signal QCU rises from L level to H level, and a refresh address is updated after the refresh operation, to prepare for the next refresh operation.

FIG. 29 is a diagram showing a correspondence between refresh address bits ZQAD<k> and ZQAD<k+1>. In one-bit counters QNT1 to QNT12 shown in FIG. 26, each time when a lower address bit ZQAD<k> rises, that is, each time when a lower address bit QAD<k> falls from H level to L level to generate a carry, a logic level of higher address bit ZQA<k+1> is altered. Therefore, by applying refresh address update signal QCU to the lowest one-bit counter QNT0, a refresh address can be updated in each refresh operation.

With the refresh address generation circuit shown in FIG. 23 provided correspondingly to each refresh cycle, a refresh address can be generated in each refresh period, thereby generating a refresh address corresponding to a refresh address issued in a different period.

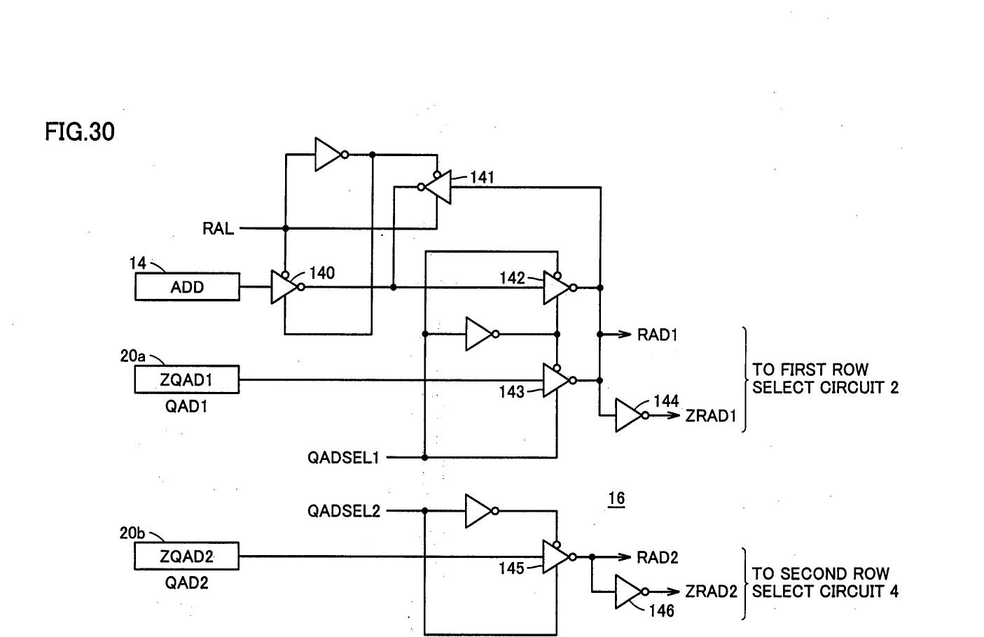

FIG. 30 is a diagram schematically showing a configuration of address select circuit (MUX) 16 shown in FIG. 1. In FIG. 30, address select circuit 16 includes: a tri-state inverter 140 passing 13-bit address signal ADD<12:0> from address input circuit 14 therethrough when row address latch instructing signal RAL is at L level; a tri-state inverter 142 activated when refresh address select signal QADSEL1 is at L level, to invert an output signal of tri-state inverter 140 to generate internal row address signal RAD1<12:0>; a tri-state inverter 143 activated when refresh address select signal QADSEL1 is at L level, to invert refresh address QAD1 (ZQAD1<12:0>) from first refresh address generation circuit 20a, to generate internal row address signal RAD1 in refresh operation; an inverter 144 inverting internal row address signal RAD1 to generate a complementary internal row address signal ZRAD1; a tri-state inverter 145 activated when refresh address select signal QADSEL2 is at H level, to invert refresh address signal QAD2 (ZQAD2<12:0>) from second refresh address generation circuit 20b to generate internal row address signal RAD2; and an inverter 146 inverting internal row address signal RAD2<12:0> outputted by tri-state inverter 145 to generate complementary internal row address signal ZRAD2<12:0>.

Internal row address signals RAD1 and ZRAD1 are 13-bit address signals complementary to each other and applied to first row select circuit 2 shown in FIG. 1 and internal row address signal RAD2 and ZRAD2 are 13-bit address signals complementary to each other and applied to second row select circuit 4 shown in FIG. 1. Address signals RAD1 and RAD2 each include a block address designating a memory block.

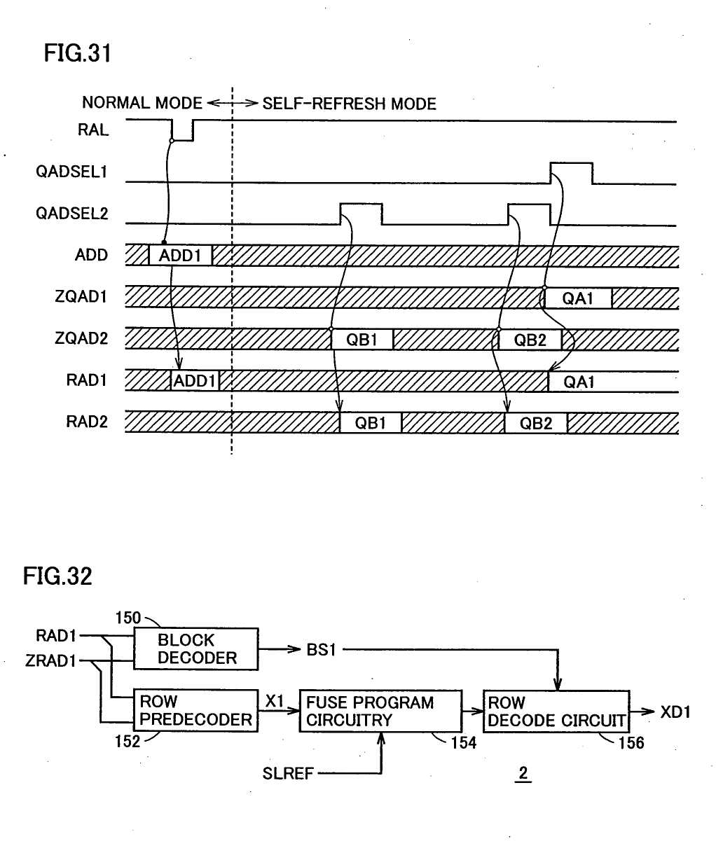

FIG. 31 is a timing chart representing an operation of address select circuit 16 shown in FIG. 30. Brief description will be given of operations in address select circuit 16 shown in FIG. 30 below with reference to FIG. 31.

In a normal operating mode in which a data access is made, refresh address select signals QADSEL1 and QADSEL2 are both at L level. Therefore, tri-state inverters 143 and 145 are in an output high impedance state, while tri-state inverter 142 is in an active state. When a row access command (a row active command) is supplied externally, row address latch signal RAL is set at L level for a prescribed period, tri-state inverter 140 is activated and address signal ADD<12:0> from address input circuit 14 is applied to tri-state inverter 142.

When row address latch signal RAL attains H level, tri-state inverter 140 enters an output high impedance state, while tri-state inverter 141 is activated to form a latch circuit with tri-state inverter 142. Accordingly, internal row address signal RAD1 is generated and latched in accordance with external address signal ADD1. It is noted that in FIG. 31, no bits of address are individually shown and instead, the names of the address signals are simply shown.

In a self-refresh mode, refresh address select signals QADSEL1 and QADSEL2 are activated at prescribed time intervals. Row address latch signal RAL is maintained at H level. Accordingly, tri-state inverter 140 is kept in an output high impedance state, while tri-state inverter 141 is kept in an active state.

When refresh address select signal QADSEL1 attains H level, tri-state inverter 142 enters an output high impedance state, while tri-state inverter 143 is activated to invert refresh address signal QAD1 (ZQAD1<12:0>) from first refresh address generation circuit 20a for generating internal row address signal RAD1. Therefore, as shown in FIG. 31, when refresh address select signal QADSEL1 is activated, internal row address signal RAD1 is generated according to refresh address QAD1 from first refresh address generation circuit 20a.

When refresh address select signal QADSEL1 attains L level, tri-state inverter 143 enters an output high impedance state, while tri-state inverter 142 is activated. Accordingly, in this state, selected refresh address QA1 is held by inverters 141 and 142.

In an update operation of a refresh address, an updated refresh address is selected after refresh operation is completed in each refreshing operation. Refresh address select circuit is deactivated to cause tri-state inverter 143 to enter into an output high impedance state according to deactivation of refresh activation signal REF after a refresh operation is completed. Therefore, refresh address select signal is issued two times in each refresh operation and updating of a latched refresh address is performed after a refresh operation is completed. Here, however, a refresh address is shown being selected upon each activation of refresh address select signal simply for description of updating/selecting operation of a refresh address. This applies to refresh address QAD2.

On the other hand, when refresh address select signal QADSEL2 is activated, a tri-state inverter 145 generates internal refresh row address signal RAD2 and inverter 146 generates complementary internal row address signal ZRAD in accordance with refresh address signal QAD2 (ZQAD2<12:0>) from second refresh address generation circuit 20b.

Therefore, as shown in FIG. 31, internal row address signal RAD2 is generated according to refresh addresses QB1 and QB2 from refresh address generation circuit 20b each time when refresh address select signal QADSEL2 rises to H level.

In address select circuit 16, in a normal operating mode, internal row address signal RAD1 is generated in accordance with external address signal ADD, while in a self-refresh mode, row address signal RAD1 is generated in accordance with refresh address signal QAD1 from first refresh address generation circuit 20a. Address signal RAD2 is generated, in a self-refresh mode, according to refresh address signal QAD2 from second refresh address generation circuit 20b.

Refresh address select signals QADSEL1 and QADSEL2 are also used as address latch signals. A corresponding refresh address is selected when each refresh request is issued, and accordingly, a corresponding refresh address can be selected correctly.

FIG. 32 is a diagram schematically showing a configuration of first row select circuit 2 shown in FIG. 1. In FIG. 32, first row select circuit 2 includes: a block decoder 150 decoding bits corresponding to a block address of internal row address signals RAD1 and ZRAD1 to generate a block select signal BS1; a row predecoder 152 predecoding the remaining address bits of internal row addresses RAD1 and RAD2 to generate a multi-bit row predecode signal X1; a fuse program circuitry 154 selectively transmitting multi-bit row predecode signal X1 for each row; and row decode circuit 156 generating row decode signal XD1 according to an output signal of fuse program circuit 154 and block select signal BS1.

Block decoder 150 and row predecoder 152 are each a NAND type decode circuit and generates a block select signal and a multi-bit predecode signal X1 based on a combination including predetermined bits.

Fuse program circuitry 154 includes fuse program circuits provided corresponding to the respective rows, for selectively transmitting a predecode signal to row decode circuits 156 provided corresponding to the respective rows. That is, fuse program circuit 154 prohibits, when a corresponding row (word line) is inferior in pause refresh characteristic, transmission of a corresponding combination of predecode signals X1 to a corresponding row decoder in a self-refresh mode.

In a normal operating mode, fuse program circuitry 154 transmits predecode signal X1 from row predecoder 152 to a row decoder for a corresponding row (word line) independently of pause refresh characteristic of a corresponding row (word line).

Self-refresh mode setting signal SLREF controls selective transmission of a predecode signal of fuse program circuitry 154 in a normal operating mode and a self-refresh mode.

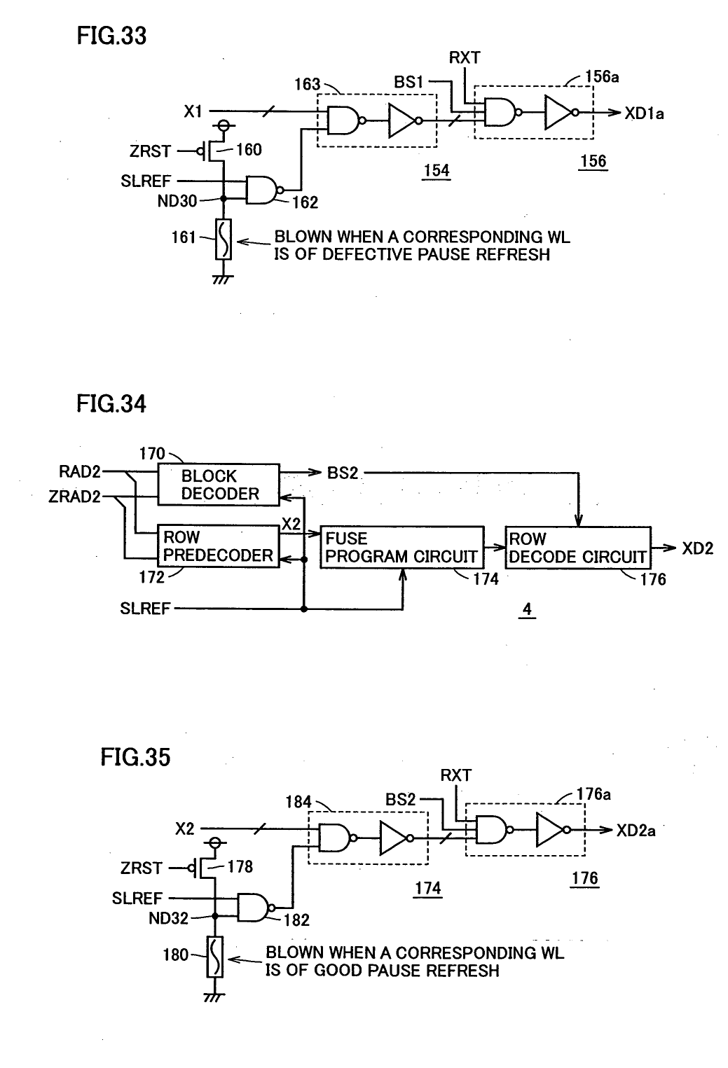

FIG. 33 is a diagram showing a configuration example of a part corresponding to one row of fuse program circuitry 154 shown in FIG. 32. In FIG. 33, fuse program circuitry 154 includes: a P-channel MOS transistor 160 for setting node N30 to a power supply voltage level according to a reset signal ZRST, a fuse element 161 connected between node N30 and ground node; a NAND circuit 162 receiving self-refresh mode setting signal SLREF and a signal on node N30; and an AND circuit 163 receiving a prescribed combination of bits of multi-bit predecode signal X1 and an output signal of NAND circuit 162.

Predecode signal X1 is a signal of a multiple of bits and signals of a prescribed combination are applied to each respective row. Reset signal ZRST is set to L level for a prescribed period when power is turned on or when a system is rest, for example. Fuse element 161 is blown if a corresponding row (word line) is of a pause refresh failure or defective in pause refresh characteristic. Blowing/non-blowing of fuse element 161 is performed in a laser trimming step of the last step in wafer process steps, after detection of a failure address based on a test result on data holding characteristic at a wafer level.

Row decode circuit 156 includes row decoders 156a provided corresponding to the respective rows. Row decoder 156a receives an output signal of AND circuit 163, block select signal BS1 and word line drive timing signal RXT to generate a one-bit decode signal (row select signal) XD1a.

In a normal operating mode, self-refresh mode setting signal SLREF is at L level and an output signal of NAND circuit 162 is at H level. Therefore, AND circuit 163 generates an output signal according to predecode signal X1 generated based on an external address signal.

In a self-refresh mode, self-refresh mode setting signal SLREF is at H level. When a corresponding row (word line WL) is of pause refresh failure, fuse element 161 is blown and node ND30 is maintained at H level. Therefore, in a self-refresh mode, an output signal of NAND circuit 162 is driven to L level, an output signal of NAND circuit 163 is fixed at L level independently of predecode signal X1, and in response, decode signal XD1a from row decoder 156a is also fixed at L level.

When a corresponding row (word line) is excellent in pause refresh characteristic, fuse element 161 is in a non-blown state and node ND30 is fixed at L level. Accordingly, an output signal of NAND circuit 162 is fixed at H level, and AND circuit 163 produces an output signal according to predecode signal X1. Therefore, in a self-refresh mode, as for a memory cell row good in pause refresh characteristic, the corresponding row is driven to a selected state according to predecode signal X1 generated based on refresh address signal QAD1 generated at a long period.

FIG. 34 is a diagram schematically showing a configuration of second row select circuit 4 shown in FIG. 1. In FIG. 34, second row select circuit 4 includes: a block decoder 170 activated when self-refresh mode setting signal SLREFT is active, to decode prescribed bits (block address) of row address signals RAD2 and ZRAD2 to generate block select signal BS2; a row predecoder 172 activated when self-refresh mode setting signal SLREF is active, to predecode remaining bits of complementary address signals RAD2 and ZRAD2; a fuse program circuit 174 selectively transmitting predecode signal X2 from row predecoder 172; and a row decode circuit 176 generating decode signal XD2 according to a signal applied from fuse program circuit 174, block select signal BS2 and a word line drive timing signal not shown.

Fuse program circuit 174 includes program circuits provided corresponding to the respective rows and transmits a corresponding predecode signal to a row decoder provided corresponding to a row inferior in pause refresh characteristic.

FIG. 35 is a diagram showing a configuration example of fuse program circuit 174 and row decode circuit 176 combined shown in FIG. 34. In FIG. 35, fuse program circuit 174 includes: a P-channel MOS transistor 178 connected between a power supply node and a node ND 32, and receiving reset signal ZRST at a gate thereof; a fuse element 180 connected between node ND32 and a ground node; a NAND gate 182 receiving a signal on node N32 and self-refresh mode setting signal SLREF; an AND circuit 184 receiving an output signal of NAND gate 182 and predecode signal X2; and a row decoder 176a receiving an output signal of AND circuit 184, block select signal BS2 and word line drive timing signal RXT to generate decode signal XD2.

Row decoders 176a are included in row decode circuit 176 and provided corresponding to each respective row, to decode a set of transmitted predecode signals in predecode signal X2.

In fuse program circuit 174 shown in FIG. 35, when a corresponding row (word line WL) is excellent in pause refresh characteristic, fuse element 180 is blown. If a corresponding row is of pause refresh failure, fuse element is maintained in a non-blown state.

In a normal operating mode, as shown in FIG. 34, row predecoder 172 is inactive, predecode signal X2 is at L level and decode signal (row select signal) XD2a is at L level of a non-selected state.

In a self-refresh mode, self-refresh mode setting signal SLREF is set in an active state at H level. If fuse element 180 is in a blown state, an output signal of NAND circuit 182 is at L level, an output signal of AND circuit 184 is at L level independently of predecode signal X2 and decode signal XD2 maintains a non-selected state at L level. Therefore, no row selection according to predecode signal X2 is performed on a memory cell row excellent in pause refresh characteristic.

When fuse element 180 is in a non-blown state, a voltage level at node ND3 is L level and an output signal of NAND circuit 182 is at H level. Therefore, in this case, row decoder 176a perform a decoding operation according to predecode signal X2 to generate decode signal XD2a. Accordingly, a memory cell row defective in pause refresh is refreshed according to refresh requests issued in short periods. Even if refresh address QAD2 is generated according to refresh request PHYS2 and applied to a row select circuit, no row selection is performed in the case where refresh address QAD2 designates a memory cell row good in pause refresh characteristic.

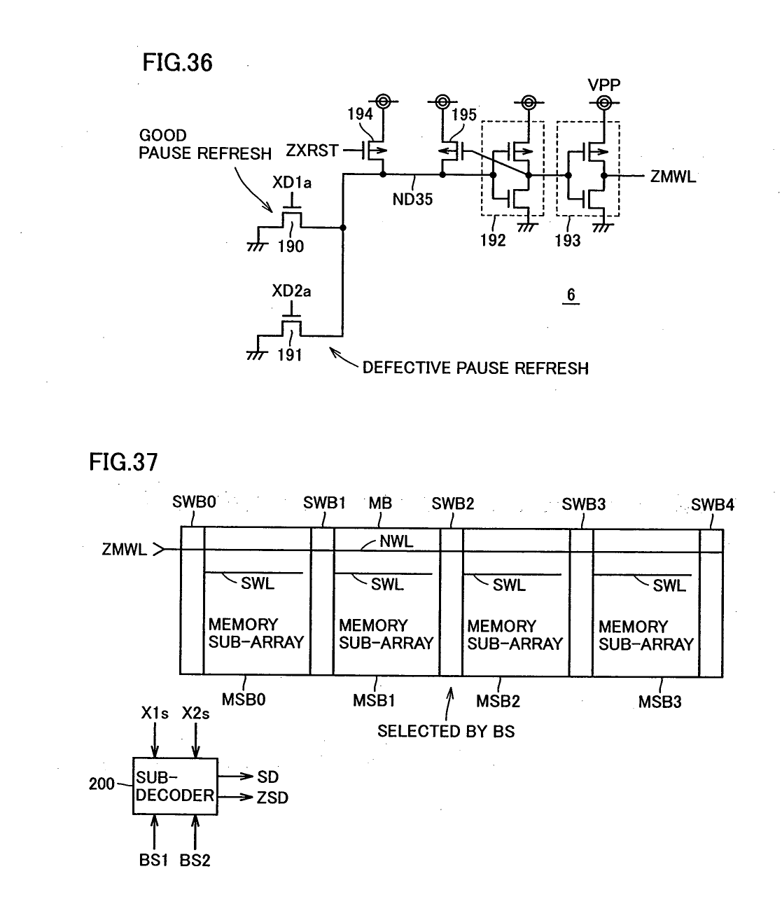

FIG. 36 is a diagram showing a configuration example of row drive circuit 6 shown in FIG. 1. In FIG. 36, there is shown a configuration of a main word line drive circuit for generating a main word line select signal ZMWL to one main word line MWL. A program on good/failure in pause refresh is executed in units of main drive circuits.

In FIG. 36, a main word line driver includes: an N-channel MOS transistor 190 selectively driving a node ND35 to a ground voltage level according to decode signal XD1a; an N-channel MOS transistor 191 selectively discharging node ND35 to ground voltage level according to decode signal XD2a; a CMOS inverter 192 inverting a signal on node N35; a CMOS inverter 193 inverting an output signal of CMOS inverter 192 to generate main word line drive signal ZMWL; a P-channel MOS transistor 194 precharging node ND35 to a high voltage VPP level when reset signal ZXRST is activated; and a P-channel MOS transistor 195 made conductive when an output signal of CMOS inverter 192 is at L level, to charge node ND35 to high voltage VPP level.

Main word line drive signal ZMWL is at L level when a corresponding main word line MWL is selected and is at high voltage VPP level when not selected. When a corresponding main word line is of pause refresh failure, decode signal XD1a is at L level in a self-refresh mode and MOS transistor 190 maintains a non-conductive state. In this state, main word line drive signal ZMWL is generated according to decode signal XD2a.

When a corresponding main word line MWL is good in pause refresh characteristic, decode signal XD2a is fixed at L level and MOS transistor 191 is maintained in a non-conductive state. Therefore, in a normal operating mode and a self-refresh mode, main word line drive signal ZMWL is generated according to decode signal XD1a.

In operation of main word line drive circuit, node N35 is precharged to high voltage VPP level according to reset signal ZXRST. Reset signal ZXRST is set to L level when row address strobe signal RAST is deactivated. When a corresponding main word line is selected, MOS transistor 190 or 191 is made conductive, node ND35 is discharged to ground voltage level, an output signal of CMOS inverter 192 attains H level and in response, main word line drive signal ZMWL from CMOS inverter 193 attains L level.

In contrast, when a corresponding main word line is in a non-selected state, MOS transistors 190 and 191 maintain a non-conductive state and node ND 35 is maintained at high voltage VPP level. In this state, an output signal of CMOS inverter 192 is at L level and in response, main word line drive signal ZMWL from CMOS inverter 193 is maintained at H level (high voltage VPP level). An output signal of CMOS inverter 192 is at L level and node ND35 is maintained at high voltage VPP level by MOS transistor 195.

Therefore, a refresh period can be altered with each main word line being a unit in accordance with goodness/failure of pause refresh.

FIG. 37 is a diagram schematically showing a configuration of one memory block shown in FIG. 1. A memory block MB is divided into a plurality of memory sub-arrays MSB0 to MSB3 in a row direction by sub-word driver bands SWB1 to SWB3. Sub-word driver bands MSB0 and MSB4 are disposed on the outsides of memory sub-arrays MSB0 and MSB3, respectively.

Main word line MWL is provided commonly to memory sub-arrays MSB0 to MSB3. Sub-word lines SWL are provided corresponding to memory cell rows in memory sub-arrays MSB0 to MSB3. A prescribed number of sub-word lines SWL are arranged corresponding to one main word line MWL in each of memory sub-arrays MSB0 to MSB3.

Sub-word drivers each driving a corresponding sub-word line SWL to a selected state according to sub-decode signals SD and ZSD and main word line drive signal ZMWL on a corresponding main word line are provided corresponding to sub-word lines SWL in sub-word driver bands SWB0 to SWB4.

Sub-decode signals SD and ZSD are generated commonly for main word lines in memory block MB. One sub-word line out of a prescribed number of sub-word lines provided corresponding to one main word line MWL is selected according to a combination of sub-decode signals SD and ZSD.

Sub-decode signals SD and ZSD are generated by sub-decoder 200 selectively decoding sub-word line predecode signals X1s and X2s in accordance with block select signals BS1 and BS2. Sub-word line predecode signal X1s and X2s are lower predecode signals of the predecode signals generated from row predecoder 152 shown in FIG. 32 and row predecoder 172 shown in FIG. 34, and generated from internal row address signals RAD1 and RAD2, respectively, according to a pause refresh characteristic.

When block select signal BS1 is generated, sub-decode signals SD and ZSD are generated based on sub-word line predecode signals X1s. When block select signal BS2 is generated, sub-decode signals SD and ZSD are generated based on sub-word line predecode signal X2s. Block select signals BS1 and BS2 are activated at different timings, and word line multi-selection that sub-word lines are simultaneously selected never occurs. Therefore, sub-word line predecode signal can be selected according to the pause refresh characteristic of a selected main word line. Thus, a pause refresh failure can be repaired in units of main word lines.

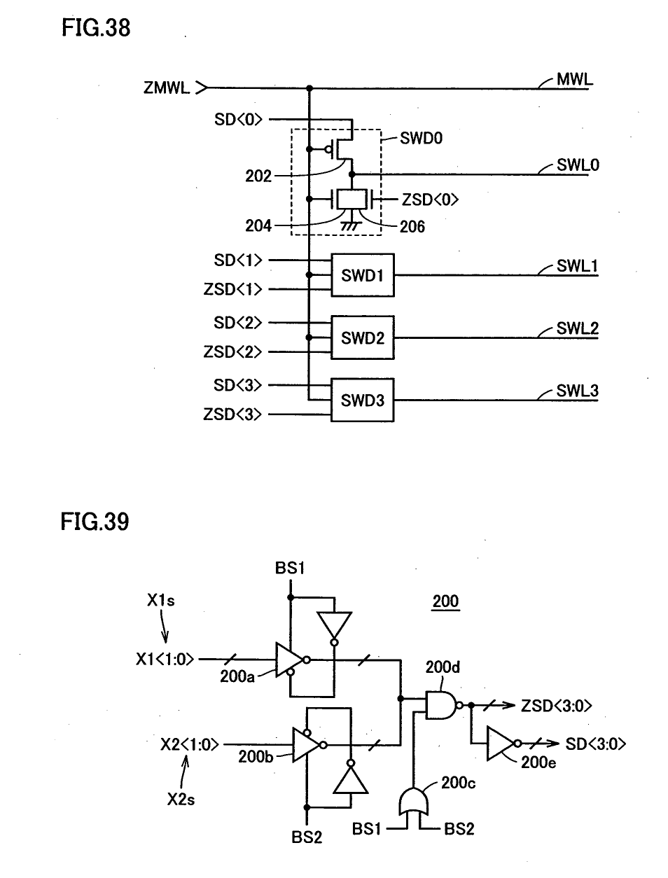

FIG. 38 is a diagram schematically showing a configuration of a part associated with one main word line in one sub-word driver band shown in FIG. 37. Sub-word lines SWL0 to SWL3, to which memory cells in corresponding rows are connected, are provided corresponding to main word line MWL. Sub-word drivers SWD0 to SWD3 are provided corresponding to sub-word lines SWL0 to SWL3, respectively.

Sub-word driver SWD0 drives sub-word line SWL0 according to sub-decode signals SD<0> and ZSD<0>, and main word drive signal ZMWL. Sub-word driver SWD1 drives sub-word line SWL1 according to sub-decode signals SD<1> and ZSD<1>, and main word line drive signal ZMWL. Sub-word driver SWD2 drives sub-word line SWL2 according to sub-decode signals SD<2> and ZSD<2>, and main word line drive signal ZMWL. Sub-word driver SWD3 drives sub-word line SWL3 according to sub-decode signals SD<3> and ZSD<3>, and main word line drive signal ZMWL.

Since sub-word driver SWD0 to SWD3 are of the same circuit configuration, in FIG. 38 there is shown a specific configuration of sub-word driver SWD0. Sub-word driver SWD0 includes: a P-channel MOS transistor 202 selectively transmitting sub-decode signal SD<0> to sub-word line SWL0 according to main word line drive signal ZMWL; an N-channel MOS transistor 204 discharging sub-word line SWL0 to ground voltage level according to main word line drive signal ZMWL; and an N-channel MOS transistor 206 driving sub-word line SWL0 to ground voltage level according to sub-decode signal ZSD<0>.

When sub-word line SWL0 is selected, main word line drive signal ZMWL is at L level and MOS transistor 204 turns into a non-conductive state. Sub-decode signal SD<0> attains H level at high voltage VPP level and is transmitted to sub-word line SWL0 through MOS transistor 202. On the other hand, when sub-decode signal SD<0> is at L level, MOS transistor 202 is kept in a non-conductive state, even if main word line drive signal ZMWL is at L level. In this situation, sub-decode signal ZSD<0> turns H level and sub-word line SWL0 is maintained at ground voltage level.

In a hierarchical word line structure of a main word line and sub-word lines as well, a sub-decode signal can be generated based on a decode signal used.

FIG. 39 is a diagram showing a configuration example of sub-decoder 200 shown in FIG. 37. In FIG. 39, sub-decoder 200 includes: a tri-state inverter 200a activated when block select signal BS1 is activated, to invert 2-bit predecode signal X1<1:0>; a tri-state inverter 200b activated when block select signal BS2 is activated, to invert and transmit 2-bit predecode signal X2<1:0>; an OR circuit 200c receiving block select signals BS1 and BS2; a NAND decode circuit 200d enabled when an output signal of OR circuit 200c is at H level, to decode output signals of tri-state inverters 200a and 200b for generating 4-bit sub-decode signal ZSD<3:0>; and an inverter circuit 200e inverting an output signal of NAND decode circuit 200d to generate 4-bit sub-decode signal SD<3:0>.

When block select signals BS1 and BS2 are both at L level, an output signal of OR circuit 200c is at L level, 4-bit sub-decode signal ZSD<3:0> from NAND decode circuit 200b is at H level in all bits, while 4-bit sub-decode signal SD<3:0> from inverter circuit 200 is at L level in all bits.

When one of block select signals BS1 and BS2 is activated, one of tri-state inverters 200a and 200b is activated and corresponding 2-bit predecode signal X1<1:0> or X2<1:0> is applied to NAND decode circuit 200d. NAND decode circuit 200d performs a decoding operation and generates 4-bit sub-decode signal ZSD<3:0> and 4-bit sub-decode signal SD<3:0> according to a result of the decoding operation.

In the configuration of sub-decoder 200 shown in FIG. 39, there is no opportunity that block select signals BS1 and BS2 are simultaneously driven to a selected state. If refresh requests PHYS1 and PUYS2 are simultaneously issued, issuance timings are made different from each other, to prevent conflict between refresh operations. Accordingly, a corresponding predecode signal can be selected to generate sub-decode signals according to each refresh period.

FIG. 40 is a diagram schematically showing a configuration of row-related control circuit 12 shown in FIG. 1. In FIG. 12, row-related control circuit 12 includes: a row address latch instruction generation circuit 210 for generating row address latch fast signal RALF according to row address strobe signal RAS; an OR circuit 211 receiving self-refresh mode setting signal SLREF and row address latch fast signal RALF to generate row address latch instructing signal RAL; a block decoder activation circuit 212 generating block decoder enable signal BDE according to an output signal of row address latch instruction generation circuit 210; a word line drive activation circuit 214 generating word line drive timing signal RXT according to an output signal of block decoder activation circuit 212; and a sense amplifier activation circuit 216 generating a sense amplifier activation signal ZS0NM according to an output signal of word line drive activation circuit 214.

Row address latch instruction generation circuit 210 sets row address latch fast signal RALF at L level for a prescribed period in response to a rise of row address strobe signal RAS. OR circuit 211 generates; when self-refresh mode setting signal SLREF is at L level, row address latch instructing signal RAL according to row address latch fast signal RALF from row address latch instruction generation circuit 210. When self-refresh mode setting signal SLRAF is set to H level, row address latch instructing signal RAL is fixed at H level. Row address latch instructing signal RAL is applied to address select circuit 16 previously shown in FIG. 30.

Row address strobe signal RAS is generated from the circuit shown in FIG. 22.

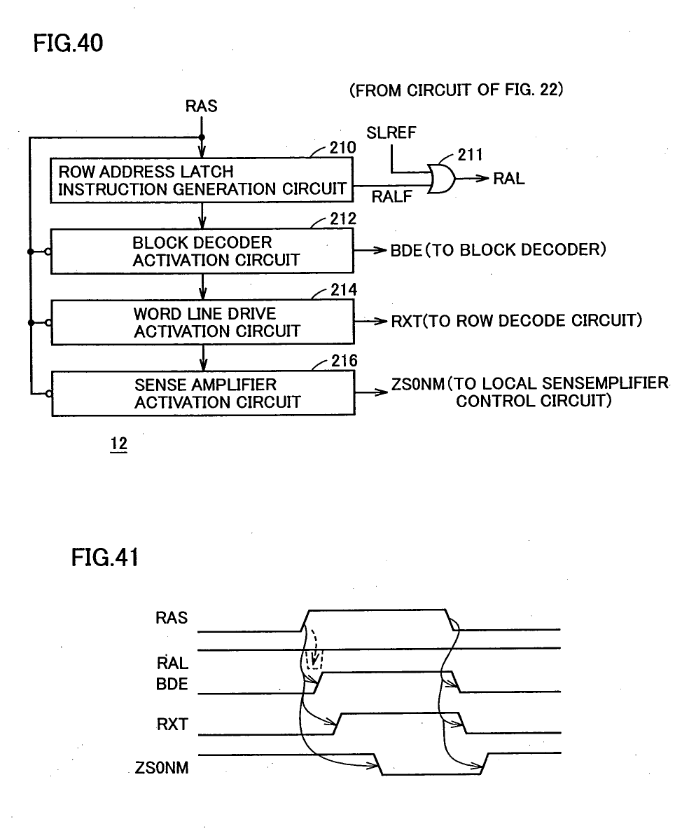

In row-related control circuitry 12, these circuits constitute delay circuits and activate, when output signals of circuits at the preceding stages are activated, respective output signals after elapse of prescribed times. When row address strobe signal RAS attains a state of L level, the circuits 212, 214 and 216 drive respective output signals to a non-active state in a prescribed sequence. Now, brief description will be given of operations in row-related control circuit 12 shown in FIG. 40 with reference to FIG. 41.

When row address strobe signal RAS is at L level, this semiconductor memory device is in a precharge state. In a self-refresh mode, self-refresh mode setting signal SLREF is at H level and row address latch instructing signal RAL is fixed at H level. Furthermore, block decoder enable signal BDE and word line drive timing signal RXT are both at L level and sense amplifier activation signal ZS0NM is at H level.

When row address strobe signal RAS rises to H level, row address latch fast signal RALF turns L level for a prescribed period of time. Furthermore, in this self-refresh mode, self-refresh mode setting signal SLRAF is at H level and row address latch instructing signal RAL maintains an H level.

In a normal operating mode in which self-refresh mode setting signal SLREF is at L level, row address latch instructing signal RAL, as shown in FIG. 41, turns L level for a prescribed period in response to a rise of row address strobe signal RAS.

When row address strobe signal RAS rises to H level, block decode enable signal BDE is at first activated by block decoder activation circuit 212 and a block decoder decodes a block address of an applied refresh address signal. Furthermore, a predecode operation is performed according to a remaining address signal of a refresh address, to generate a predecode signal. When block decode enable signal BDE is activated, then word line drive activation circuit 214 drives word line drive timing signal RXT to H level. Responsively, a word line (main and sub-word lines) for an addressed row is driven to a selected state. When a word line is selected and data of a memory cell connected to a selected word line (sub-word line) is read out onto a corresponding bit line, sense amplifier activation signal ZS0NM is activated, a sensing operation is performed and sensing, amplification and latching of data in a memory cell are performed. Data latched by the sense amplifier is rewritten to an original memory cell to refresh memory data.

When a prescribed time elapses in a self-refresh mode, row address strobe signal RAS turns L level, block decoder activation circuit 212, word line drive activation circuit 214 and sense amplifier activation circuit 216 are deactivated in a prescribed sequence, block decoder enable signal BDE and word line drive timing signal RXT are driven to L level, and sense amplifier activation signal ZS0NM is driven to H level. Thus, one refresh operation is completed.

Therefore, a predecoder and a row decoder are provided with gate circuits corresponding to pause refresh characteristic, to perform a predecoding operation and a decoding operation according to refresh addresses issued in different periods, and each word line can be refreshed in a refresh period adapted to a pause refresh characteristic. Modification of Refresh Period Issuing Section:

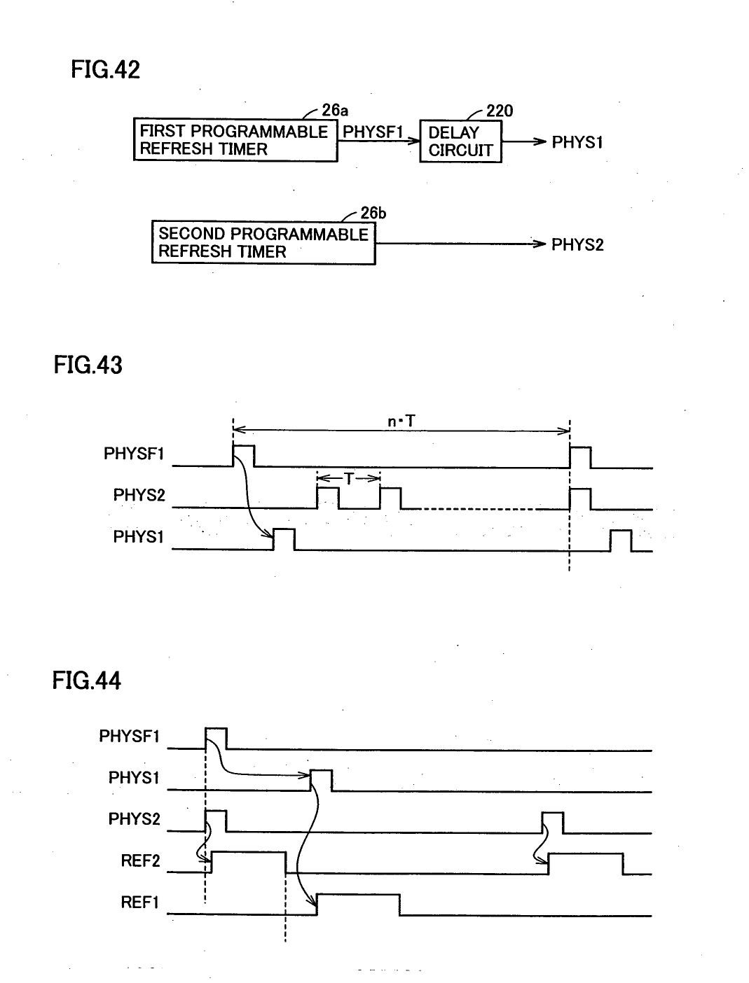

FIG. 42 is a diagram showing a modification of the refresh period issuing section. In a configuration shown in FIG. 42, there is provided a delay circuit 220 delaying refresh request fast PHYSF from first programmable refresh timer 26a shown in FIG. 2, to issue refresh request PHYS.

Refresh request PHYS2 is issued from second programmable refresh timer 26b. Delay circuit 220 delays refresh request fast PHYSF1 by a prescribed period to issue refresh cycle PHYS1. A delay time that delay circuit 220 has is a period of time necessary for refreshing of data, that is, a time period from start of selection of a memory cell till completion of rewrite (restoring) of memory cell data, and a time period when refresh activation signal REF is active. A time period of refresh to be executed when a refresh request is issued is secured by refresh activation signal REF. Accordingly, as described later, due to delaying by refresh time period, even if refresh requests PHYSF1 and PHYSF2 are simultaneously issued, refresh of a memory cell excellent in pause refresh characteristic can be executed after refresh of a memory cell defective in pause refresh characteristic is completed. Thus, conflict between refresh operations can be prevented.

Configurations of programmable refresh timers 26a and 26b are the same as the configuration that is previously described in FIG. 6 to FIG. 10. In a case where count values of programmable refresh timers 26a and 26b are programmed, refresh requests PHYSF1 and PHYSF2 might be simultaneously issued if an issuance cycle of refresh request PHYS2 is set to an integer multiple of an issuance cycle of refresh request fast PHYSF1, for example. In a case where refreshes are simultaneously executed on memory cells in memory blocks sharing no sense amplifier, no data conflict occurs and refresh of data can be correctly performed even if the refresh is performed simultaneously.

However, there is a possibility that different sub-word lines are simultaneously selected in the same memory block according to fresh requests PHYS1 and PHYS2. Therefore, delay circuit 220 is provided to prevent simultaneous issuance of refresh requests PHYS1 and PHYS2.

A situation, as shown in FIG. 43, is considered where second programmable refresh timer 26b issues refresh request PHYS2 at periods T when first programmable refresh timer 26a issues refresh request fast PHYSF1 at intervals of n·T. In this case, refresh request PHYS2 and refresh request fast PHYSF1 are simultaneously issued every n cycles. In this state, refresh request fast PHYSF1 is delayed by delay circuit 220. Refresh of memory cell of a defective pause refresh characteristic is first performed according to refresh request PHYS2 and after completion of the refreshing, then, refresh of a memory cell excellent in pause refresh characteristic is executed according to refresh request PHYS1.

FIG. 44 is a timing chart representing an operation in the case where refresh request PHYS2 and refresh request fast PHYSF1 are concurrently issued. When refresh request PHYS2 is issued, refresh activation signal REF2 is activated, by the circuitry shown in FIG. 20, for a prescribed period. When refresh activation signal REF2 turns into an inactive state, refresh request PHYS1 is issued from delay circuit 220 and refresh activation signal REF1 is activated. Refresh operations are executed according to the respective refresh activation signals REF2 and REF1 (when a refresh address coincides with a programmed address). Conflict between refreshing operations can be prevented using delay circuit 220.

Usually, active periods of refresh activation signal REF1 and REF2 are each tens of ns (nanoseconds), while an issuance period of refresh request PHYS2 is in the range from hundreds of ns to several μs (microseconds). An issuance period of refresh request PHYS1 is, for example, 16 μs in a standard DRAM. Accordingly, a delay time that delay circuit 220 has is sufficiently shorter as compared with the issuance period of refresh request PHYS1, and an amount of held charges in a memory cell is sufficiently large, and data in a memory cell can be refreshed with certainty.

Detailed Configuration of Sense Amplifier:

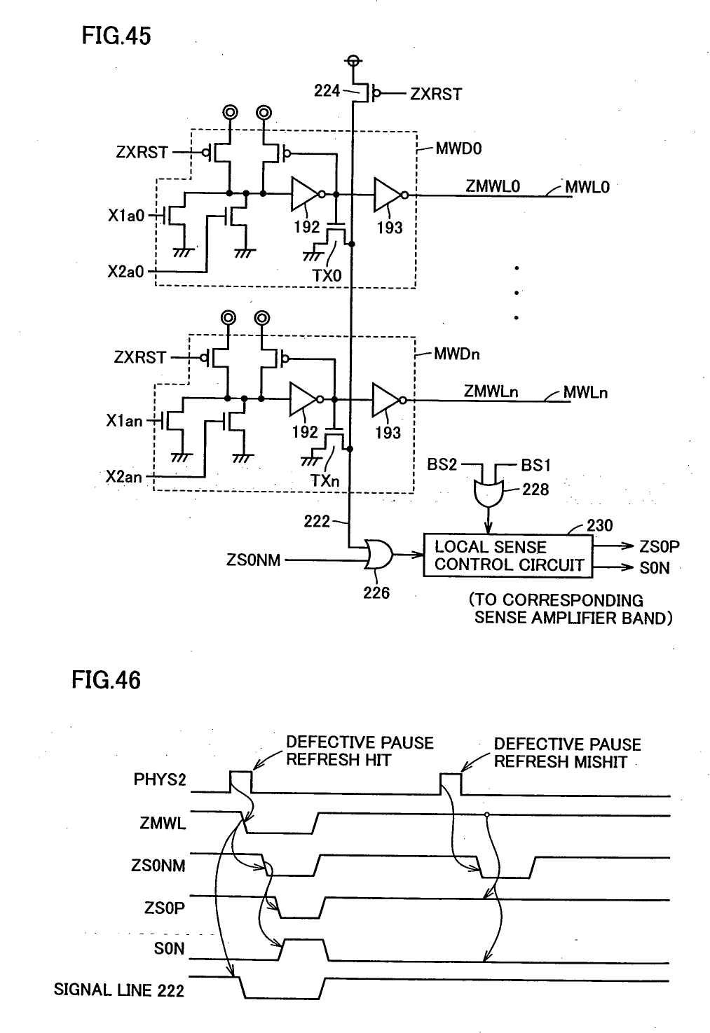

FIG. 45 is a diagram schematically showing a configuration of a section for controlling sense amplifiers included in a sense amplifier band provided corresponding to the memory blocks. In FIG. 45, main word drivers MWD0 to MWDn generating main word line drive signals ZMWL0 to ZMWLn are provided corresponding to main word lines MWL0 to MWLn, respectively. Main word drivers MWD0 to MWDn are the same in configuration as the main word driver shown in FIG. 36.

Main word driver MWD generates main word line drive signal ZMWL0 according to decode signals X1a0 or X2a0. Main word driver MWDn generates main word line drive signal ZMWLn according to decode signals X1an or X2an.

A signal line 222 is provided commonly to main word drivers MWD0 to MWDn. Signal line 222 is precharged to power supply voltage level through a P-channel MOS transistor 224 made conductive in a standby state in response to reset signal ZXRST. In addition to the configuration shown in FIG. 36, drive transistors TX0 to TXn, which are selectively made conductive according to an output signal of CMOS inverter 192, to discharge signal line 222 to ground voltage level, are provided corresponding to main word drivers MWD0 to MWDn, respectively.

Therefore, when either one of main word lines MWL0 to MWLn is driven to a selected state, an associated one of drive transistors TX0 to TXn is made conductive to discharge signal line 222 to ground voltage level. When all of main word lines MWL0 to MWLn are in a non-selected state, all of drive transistors TX0 to TXn are in a non-conductive state to maintain the signal line 222 at the precharge voltage level.

In order to control sense amplifiers, there are provided an OR circuit. 226 receiving a signal on signal line 222 and sense amplifier activation signal ZS0NM, and a local sense control circuit 230 for generating sense activation signals ZS0P and S0N for a corresponding sense amplifier band according to an output signal of OR circuit 226. Local sense control circuit 230 is selectively activated according to an output signal of OR circuit 228 receiving block select signals BS1 and BS2. When one of memory blocks sharing a corresponding sense amplifier band with each other is selected, local sense control circuit 230 is enabled to generate local sense control signals ZS0P and ZS0N according to an output signal of OR circuit 226. Therefore, OR circuit 228 is provided to each respective pair of memory blocks sharing a sense amplifier band with each other.

FIG. 46 is a signal waveform diagram representing an operation of the sense amplifier control section shown in FIG. 45. Description will now be given of operations in the sense control section shown in FIG. 45 with reference to FIG. 46. When refresh request PHYS2 is issued and a defective pause refresh address is designated, main word line drive signal ZMWL is driven to L level according to decode signal X2 (one of X2a0 to X2an) and in response, one of main word line MWL0 to MWLn is driven to a selected state.

When a prescribed period of time elapses, sense amplifier activation signal ZS0NM is activated by sense amplifier activation circuit 216 shown in FIG. 40. Since one of main word line MWL0 to MWLn is in a selected state, an associated one of drive transistors TX0 to TXn turns conductive to discharge signal line 222 to ground voltage level. Responsively, sense amplifier activation signal ZS0NM is applied to local sense control circuit 230 through OR circuit 226. In this case, the output signal of OR circuit 228 is driven to H level according to block select signal BS2, local sense control circuit 230 drives sense control signal ZS0P to L level and local sense control signal S0N to H level. Thereby, a sense amplifier is activated in a corresponding sense amplifier band, memory cell data read out onto a bit line is sensed and amplified, and rewriting (restoring) of data is performed.

When a prescribed period of time elapses, main word line drive signal ZMWL turns H level and sense amplifier activation signal ZS0NM also turns H level. In response, local sense control circuit 230 drives local sense control signal ZS0P to H level and local sense control signal S0N to L level. Thus, refresh of data of a memory cell of pause refresh failure is executed with certainty.

When the next refresh request PHYS2 is issued, an updated refresh address is also simultaneously issued. In a case where the refresh address designates a memory cell row different from a memory cell row of pause refresh failure, all of main word lines MWL0 to MWLn are in a non-selected state. Signal line 222 is precharged to power supply voltage level by MOS transistor 224 after the refreshing operation is completed. Therefore, in this state, all of drive transistors TX0 to TXn are in a non-conductive state to maintain signal line 222 at H level. Accordingly, even if the row-related control circuit shown in FIG. 40 operates according to refresh request PHYS2 to activate the sense activation signal ZS0NM, the output signal of OR circuit 226 is at H level and therefore, local sense control circuit 230 maintains local sense control signals ZA0P and S0N in an inactive state. Thus, all of sense amplifiers in the sense amplifier band are maintained in an inactive state.

Memory cell rows of pause refresh failure are sufficiently fewer than memory cell rows of normal self-refresh characteristic. Therefore, a memory cell row selected according to refresh address QAD2 is not always driven to a selected state in the same period as an issuance period of refresh request PHYS2. A refresh cycle of a memory cell row (word line) of pause refresh failure is merely made shorter as compared with a refresh cycle (for example 64 ms) of another normal memory cell row (word line). Therefore, even when refresh request PHYS2 is issued, if refresh address QAD2 designates a memory cell row excellent in pause refresh characteristic, no word line is selected. Accordingly, in this situation, an operation of sense amplifiers is ceased. Furthermore, in the case when refresh request PHYS1 is issued and refresh address QAD1 designates a memory cell row of pause refresh failure, the memory cell row is not driven to a selected state even if refresh request PHYS1 is issued. Therefore, in this case as well, an operation of the sense amplifier circuit is ceased. According to such a configuration, an operation of the sense amplifier circuit, in which a current is consumed most greatly in a self-refresh mode, is ceased to reduce a current dissipation with certainty.

A refresh cycle for a memory cell row of defective pause refresh characteristic is set to the same order as that in the worst case, as is cone conventionally, and a refresh cycle of other memory cell rows are sufficiently expanded. As compared with a conventional scheme, the number of times of refresh can be greatly decreased and furthermore current dissipation can be reduced with certainty since a sense amplifier circuit operates only when a memory cell is selected.

It is noted that there an arbitration circuit may be provided for refresh requests PHYS1 and PHYS2 to avoid a refresh conflict. When refresh requests PHYS1 and PHYS2 are both issued, refresh activation signal REF2 is activated according to refresh request PHYS2 and thereafter, refresh activation signal REF1 is activated according to refresh request PHYS1. When an output signal of an AND circuit receiving refresh request fasts PHYSF1 and PHYSF2 attain H level, refresh request PHYS2 is first issued and the issuance of refresh request PHYS1 is delayed for deactivation of refresh activation signal REF2. With such a configuration as well, refresh conflict can be avoided. Refresh of memory cells of pause refresh failure is executed first, and therefore, data can be refreshed with certainty.

It is noted that in an auto-refresh mode, a refresh command is externally supplied. In this case, an auto-refresh request is issued in consideration of the worst pause refresh characteristic. Thus, data can be certainly held even in a memory cell row of a defective pause refresh characteristic in accordance with an external address.

As described above, according to the present invention, there are provided refresh request issuing circuits different in refresh request issuance period from each other and associated refresh address generation circuits. In addition, row decode circuits are provided corresponding to respective refresh addresses for the different requests. Memory cells can be refreshed in optimal cycles adapted to pause refresh characteristics. In a self-refresh mode, refresh is preformed in a shorter cycle only on memory cells defective in pause refresh characteristic, while refresh is performed in a longer cycle on memory cells good in pause refresh characteristic. Memory cell rows of pause refresh failure are much fewer than memory cell rows of pause refresh goodness. Therefore, by refreshing memory cells excellent in pause refresh characteristic in a longer period, the number of times of refresh (sense and amplifying operations) can be reduced, which achieves a great reduction in current dissipation in a self-refresh mode.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor memory device comprising:
a plurality of memory cells, arranged in rows and columns, each for storing information;
a first refresh timer for issuing a first refresh request at a first period;
a first refresh address generation circuit for generating and outputting a first refresh address in accordance with said first refresh request;
a second refresh timer for issuing a second refresh request at a period shorter than the first period;
a second refresh address generation circuit for generating a second refresh address independently of the first refresh address; and
a plurality of row select circuits, provided corresponding to memory cell rows, each for driving a corresponding row to a selected state in accordance with a received address signal, each row select circuit driving an addressed row to a selected state in accordance with one of said first refresh address and said second refresh address, and a response relation to the first and second refresh addresses in each row select circuit being alternatively set.

2. The semiconductor memory device according to claim 1, further comprising:
a first address select circuit for selecting said first refresh address in accordance with said first refresh request, to supply a selected first refresh address to the row select circuits; and
a second address select circuit for selecting said second refresh address in accordance with said second refresh request, to supply a selected second refresh address to the row select circuits.

3. The semiconductor memory device according to claim 1, wherein
each of said row select circuits includes a program circuit for programming a refresh address designating a memory cell row to be refreshed.

4. The semiconductor memory device according to claim 3, wherein
said program circuit validates one of said first refresh address and said second refresh address.

5. The semiconductor memory device according to claim 1, wherein
said second refresh address generation circuit includes a count circuit performing a counting operation in accordance with said second refresh request, to generate said second refresh address.

6. The semiconductor memory device according to claim 1, wherein
each of said row select circuits includes:
a first decode circuit for decoding said first refresh address signal;
a second decode circuit for decoding said second refresh address signal;
a row drive circuit for driving a corresponding memory cell row to a selected state in accordance with output signals of the first and second decode circuits; and
a program circuit for setting either one of said first and second decode circuits in an operable state.

7. The semiconductor memory device according to claim 1, wherein
said first refresh address generation circuit includes an address count circuit performing a counting operation in accordance with said first refresh request to generate the first refresh address, and
said semiconductor memory device further comprises;
an address select circuit for selecting said first refresh address to supply, in place of an externally applied address signal, a selected first refresh address to the row select circuits in accordance with said first refresh request.

8. The semiconductor memory device according to claim 1, wherein
said plurality of memory cells are divided into a plurality of memory blocks each including a plurality of memory cells arranged in rows and columns, and
the first and second refresh addresses each includes a block address designating a memory block.

9. The semiconductor memory device according to claim 1, further comprising:
a conflict avoiding circuit for preventing a conflict in issuance timing between the first and second refresh requests.

10. The semiconductor memory device according to claim 9, wherein
said conflict avoiding circuit includes a delay circuit for delaying one of said first and second refresh requests by a prescribed time.
